(19) United States
(12) Patent Application Publication
(10) Pub. No.: US 2026/0353989 A1
(43) Pub. Date: Nov. 5, 2026

(54) DISPLAY PANEL AND DISPLAY DEVICE

(71) Applicant: Hubei Yangtze Industrial Innovation Center Of Advanced Display Co., Ltd., Wuhan (CN)

(72) Inventor: Yu CAI, Wuhan (CN)

(73) Assignee: Hubei Yangtze Industrial Innovation Center Of Advanced Display Co., Ltd., Wuhan (CN)

(21) Appl. No.: 19/723,527

(22) Filed: Jun. 29, 2026

(30) Foreign Application Priority Data
Jan. 28, 2026 (CN) 202610121942.8

(51) Int. Cl. H10K 59/80; H10K 50/19; H10K 59/35

(52) U.S. Cl. CPC H10K 59/876; H10K 50/19; H10K 59/35; H10K 59/80515; H10K 59/80521; H10K 59/8792

(57) ABSTRACT

Provided are a display panel and a display device. Sub-pixels in the display panel include a first sub-pixel and a second sub-pixel having the same emitted color, and the maximum light-emitting viewing angle of the first sub-pixel is smaller than that of the second sub-pixel. Display modes of the display panel include a sharing display mode and a privacy-protection display mode. In the sharing display mode, the first sub-pixel and the second sub-pixel emit light; in the privacy-protection display mode, the first sub-pixel emits light, and the second sub-pixel does not emit light. A first anode and a first cathode in the first sub-pixel form a first microcavity structure, and a second anode and a second cathode in the second sub-pixel form a second microcavity structure.

### CROSS-REFERENCE TO RELATED APPLICATION(S)

This application claims priority of a Chinese Patent Application filed with China National Intellectual Property Administration (CNIPA) on Jan. 28, 2026, with application No. 202610121942.8, the disclosure of which is incorporated herein by reference in its entirety.

### TECHNICAL FIELD

The present application relates to the technical field of display panels, particularly a display panel and a display device.

### BACKGROUND

With the continuous development of display technologies, display panels have been widely applied in production and daily life.

Further, a display panel includes various light-emitting elements configured to implement different display states of the display panel, such as a sharing mode and a privacy protection mode. With prolonged use of the display panel, different light-emitting elements in the display panel may have different problems, thereby adversely affecting the overall display performance of the display panel.

### SUMMARY

Embodiments of the present application provide a display panel and a display device. The display uniformity of the display panel can be ensured by adjusting the distances of microcavity structures of different light-emitting elements to be different.

In a first aspect, an embodiment of the present application provides a display panel. The display panel includes a substrate and multiple sub-pixels located on one side of the substrate.

The multiple sub-pixels include a first sub-pixel and a second sub-pixel that have the same emitted color, and the maximum light-emitting viewing angle of the first sub-pixel is smaller than the maximum light-emitting viewing angle of the second sub-pixel.

Display modes of the display panel include a sharing display mode and a privacy-protection display mode; in the sharing display mode, the first sub-pixel and the second sub-pixel are configured to emit light; in the privacy-protection display mode, the first sub-pixel is configured to emit light, and the second sub-pixel is not configured to emit light.

The first sub-pixel includes a first anode and a first cathode, and the first anode and the first cathode form a first microcavity structure; the second sub-pixel include a second anode and a second cathode, and the second anode and the second cathode form a second microcavity structure; along a first direction, a distance between the first anode and the first cathode is L1, and a distance between at least part of the second anode and at least part of the second cathode is L2. The first direction is the thickness direction of the display panel.

An emission wavelength of the first sub-pixel is λ1, and an emission wavelength of the second sub-pixel is λ2, L1=n×(λ1/2), L2≠m×(λ2/2), and n and m are both positive integers.

In a second aspect, an embodiment of the present application provides a display device. The display device includes the display panel described in the first aspect.

### BRIEF DESCRIPTION OF DRAWINGS

To illustrate technical solutions in the embodiments of the present application more clearly, drawings used in the description of the embodiments of the present application are described briefly hereinafter. Apparently, the drawings described hereinafter only illustrate part of the embodiments of the present application, and those skilled in the art may obtain other drawings based on the contents and drawings described in the embodiments of the present application on the premise that no creative work is done.

FIG. 1 is a diagram illustrating the structure of a display panel according to an embodiment of the present application.

FIG. 2 is a cross-sectional view taken along A-A′ of FIG. 1.

FIG. 3 is another diagram illustrating the structure of a display panel according to an embodiment of the present application.

FIG. 4 is a cross-sectional view taken along B-B′ of FIG. 3.

FIG. 5 is a cross-sectional view taken along C-C′ of FIG. 1.

FIG. 6 is a graph of the relationship between a viewing-angle brightness and a light-emitting viewing angle of a sub-pixel according to the present application.

FIG. 7 is an enlarged diagram of a first sub-pixel according to the present application.

FIG. 8 is an enlarged diagram of a second sub-pixel according to the present application.

FIG. 9 is another enlarged diagram of a first sub-pixel according to the present application.

FIG. 10 is another enlarged diagram of a second sub-pixel according to the present application.

FIG. 11 is another enlarged diagram of a second sub-pixel according to the present application.

FIG. 12 is another enlarged diagram of a second sub-pixel according to the present application.

FIG. 13 is a cross-sectional view taken along D-D′ of FIG. 1.

FIG. 14 is a cross-sectional view taken along E-E′ of FIG. 1.

FIG. 15 is a cross-sectional view taken along F-F′ of FIG. 3.

FIG. 16 is a diagram illustrating the connection of a first pixel circuit with a first sub-pixel and a second sub-pixel according to an embodiment of the present application.

FIG. 17 is another cross-sectional view taken along B-B′ of FIG. 3.

FIG. 18 is another diagram illustrating the structure of a display panel according to an embodiment of the present application.

FIG. 19 is another cross-sectional view taken along B-B′ of FIG. 3.

FIG. 20 is a diagram illustrating the structure of a display device according to an embodiment of the present application.

### DETAILED DESCRIPTION

The present application is further described in detail in conjunction with the drawings and the embodiments. It is to be understood that the embodiments set forth below are intended to illustrate and not to limit the present application. Additionally, it is to be noted that for ease of description, only part, not all, of structures related to the present application are illustrated in the drawings.

In the description of the present application, unless otherwise expressly specified and limited, the term “connected to each other”, “connected”, or “fixed” is to be construed in a broad sense, for example, as fixedly connected, detachably connected, or integrated; mechanically connected or electrically connected; directly connected to each other or indirectly connected to each other via an intermediary; or internally connected or an interactional relationship between two components. For those of ordinary skill in the art, specific meanings of the preceding terms in the present application can be construed depending on specific contexts.

In the present application, unless otherwise expressly specified and limited, when a first feature is described as “above” or “below” a second feature, the first feature and the second feature may be in direct contact, or be in contact via another feature between the two features. Moreover, when the first feature is described as “on”, “above”, or “over” the second feature, the first feature is right on, above, or over the second feature, or the first feature is obliquely on, above, or over the second feature, or the first feature is simply at a higher level than the second feature. When the first feature is described as “under”, “below”, or “underneath” the second feature, the first feature is right under, below, or underneath the second feature, or the first feature is obliquely under, below, or underneath the second feature, or the first feature is simply at a lower level than the second feature.

In the description of this embodiment, the orientation or position relationships indicated by terms such as “above”, “below”, and “right” are based on the drawings. These orientation or position relationships are intended to facilitate the description and simplify an operation and not to indicate or imply that a referred device or element must have a specific orientation or must be constructed and operated in a specific orientation. Thus, these orientation or position relationships are not to be construed as limiting the present application. Moreover, terms “first” and “second” are only used for descriptive purposes and have no special meanings.

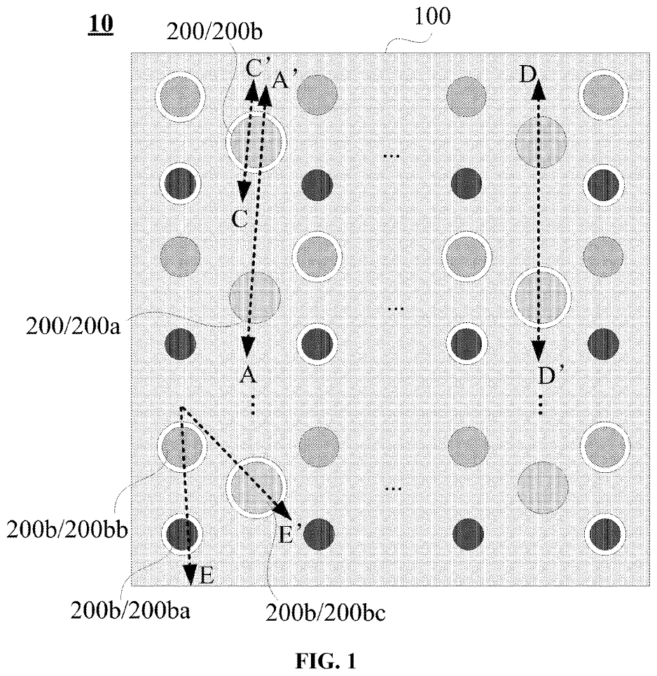

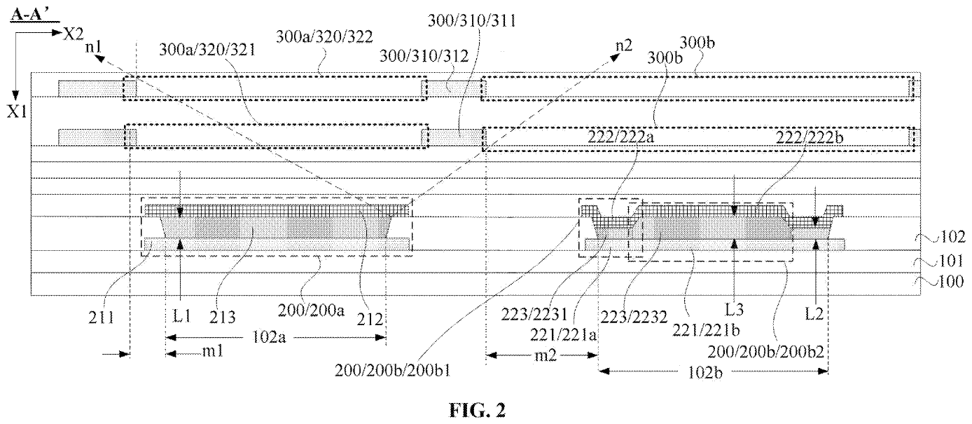

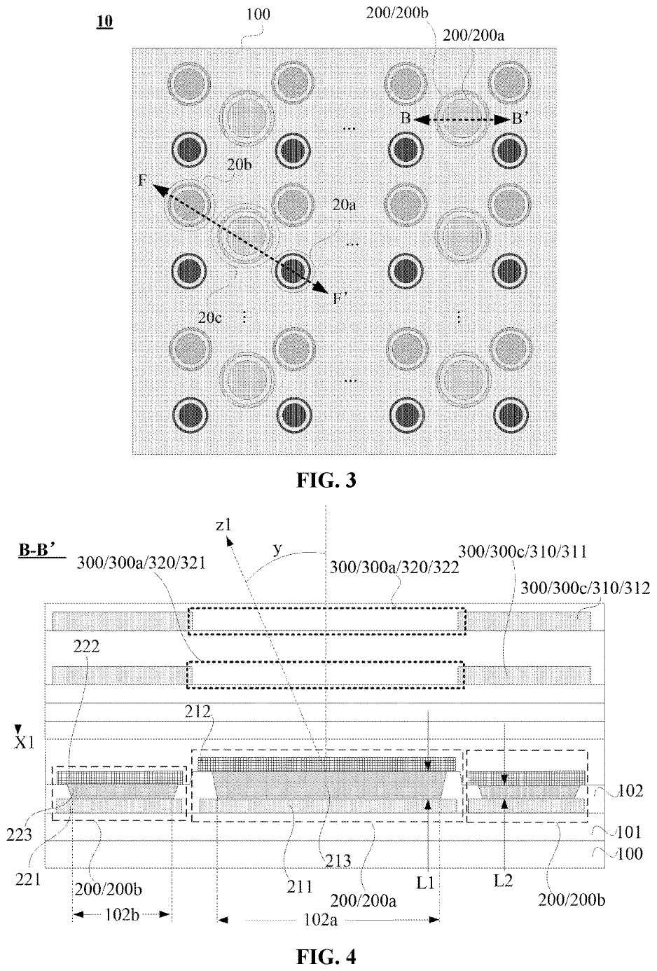

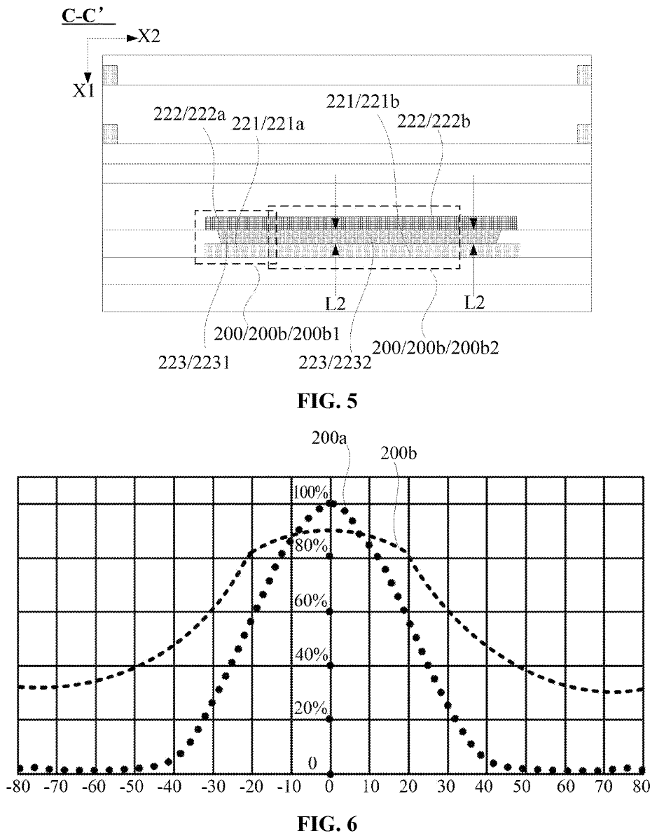

FIG. 1 is a diagram illustrating the structure of a display panel according to an embodiment of the present application. FIG. 2 is a sectional view taken along A-A′ of FIG. 1. FIG. 3 is another diagram illustrating the structure of a display panel according to an embodiment of the present application. FIG. 4 is a cross-sectional view taken along B-B′ of FIG. 3. FIG. 5 is a cross-sectional view taken along C-C′ of FIG. 1. Referring to FIGS. 1 to 5, an embodiment of the present application provides a display panel 10. The display panel 10 includes a substrate 100 and multiple sub-pixels 200 located on one side of the substrate 100. The multiple sub-pixels 200 include first sub-pixels 200a and second sub-pixels 200b that have the same emitted color. The maximum light-emitting viewing angle of a first sub-pixel 200a is smaller than the maximum light-emitting viewing angle of a second sub-pixel 200b. Display modes of the display panel 10 include a sharing display mode and a privacy-protection display mode. In the sharing display mode, both the first sub-pixels 200a and the second sub-pixels 200b emit light, and in the privacy-protection display mode, the first sub-pixels 200a emit light, and the second sub-pixels 200b do not emit light. The first sub-pixel 200a includes a first anode 211 and a first cathode 212, and the first anode 211 and the first cathode 212 form a first microcavity structure. The second sub-pixel 200b includes a second anode 221 and a second cathode 222, and the second anode 221 and the second cathode 222 form a second microcavity structure. Along a first direction X1, the distance between the first anode 211 and the first cathode 212 is L1, and the distance between at least part of the second anode 221 and at least part of the second cathode 222 is L2. The first direction X1 is the thickness direction of the display panel 10. The emission wavelength of the first sub-pixel 200a is λ1, and the emission wavelength of the second sub-pixel 200b is λ2. L1=n×(λ1/2), L2≠m×(λ2/2), and n and m are both positive integers.

In conjunction with FIGS. 1 to 5, the display panel 10 includes the substrate 100 and the multiple sub-pixels 200 located on the side of the substrate 100. The sub-pixels 200 may include sub-pixels of different colors, for example, at least one of red sub-pixels, green sub-pixels, blue sub-pixels, or white sub-pixels. Moreover, a sub-pixel 200 may be one of an organic light-emitting diode (OLED), a micro organic light-emitting diode, or a micro light-emitting diode. Using an example in which the sub-pixel 200 in FIGS. 1 to 5 includes the organic light-emitting diode, the sub-pixel 200 may include an anode, a cathode, and a light-emitting structure located between the anode and the cathode. The light-emitting structure may include multiple light-emitting material layers, and the light-emitting material layers may specifically include a hole injection layer, a hole transport layer, an electron blocking layer, a light-emitting layer, an electron transport layer, a hole blocking layer, and an electron injection layer, but are not limited thereto. Alternatively, the light-emitting structure may also include a charge generation layer, such as a p-type charge generation layer or an n-type charge generation layer. When a voltage is applied between the anode and the cathode of the organic light-emitting diode, holes transported through the hole transport layer and electrons transported through the electron transport layer move to the light-emitting layer to form excitons, fulfilling the display function of the display panel 10. In one or more embodiments, referring to FIGS. 2, 4, and 5, the display panel 10 further includes an array substrate layer 101 located on the side of the substrate 100. The array substrate layer 101 includes circuit structures of the sub-pixels 200 (not specifically shown in the figures), which supply electrical signals to light-emitting elements of the sub-pixels 200 (not specifically shown in the figures) to enable the light-emitting elements to emit light.

Further, referring to FIGS. 1 and 3, the sub-pixels 200 include the first sub-pixel 200a and the second sub-pixel 200b that have different light-emitting viewing angles, and the maximum light-emitting viewing angle of the first sub-pixel 200a is smaller than that of the second sub-pixel 200b.

Specifically, referring to FIGS. 2, 4, and 5, the display panel 10 further includes a pixel definition layer 102. The pixel definition layer 102 is provided with multiple pixel openings that may be used to define light-emitting regions of the sub-pixels 200. The multiple sub-pixels 200 include the first sub-pixels 200a and the second sub-pixels 200b. Accordingly, referring to FIG. 2, the pixel definition layer 102 includes first pixel openings 102a and second pixel openings 102b. At least part of the first sub-pixel 200a is located within a first pixel opening 102a; that is, at least part of the film structure of the first sub-pixel 200a is located within the first pixel opening 102a. The first pixel opening 102a can define at least part of a light-emitting region of the first sub-pixel 200a. Similarly, at least part of the second sub-pixel 200b is located within a second pixel opening 102b; that is, at least part of the film structure of the second sub-pixel 200b is located within the second pixel opening 102b. The second pixel opening 102b can define at least part of a light-emitting region of the second sub-pixel 200b. In the display panel 10, the pixel definition layer 102 and the pixel openings are provided to define at least part of the light-emitting regions of the sub-pixels 200 and at least part of the light-emitting layers of the sub-pixels 200 so that crosstalk between sub-pixels 200 of different colors can be reduced, and the light-emitting contrast between different sub-pixels 200 can be enhanced.

Further, referring to FIGS. 2, 4, and 5, the display panel 10 further includes a light-emitting adjustment structure 300 located on a light emission side of the sub-pixels 200. The light-emitting adjustment structure 300 includes a light-shielding layer 310 that can block the transmission of light. Therefore, the light-shielding layer 310 is set to adjust the light-emitting viewing angles of the sub-pixels 200 that overlap the light-shielding layer 310. In FIGS. 2, 4, and 5, the display panel 10 including multiple light-shielding layers 310 is used as an example for illustration. The display panel 10 includes a first light-shielding layer 311 and a second light-shielding layer 312. The number of light-shielding layers 310 may be adaptively adjusted according to actual requirements. Specifically, the light-shielding layer 310 includes light-shielding openings 320. A light-shielding opening 320 at least partially overlaps the first sub-pixel 200a. At least part of light emitted by the first sub-pixel 200a can be emitted through the light-shielding opening 320. Specifically, referring to FIGS. 2, 4, and 5, the orthographic projection of the light-shielding opening 320 on the substrate 100 overlaps the orthographic projection of a central region of the first sub-pixel 200a on the substrate 100. In this manner, at least part of light emitted by the first sub-pixel 200a at a front viewing angle or at a small viewing angle can be emitted through the light-shielding opening 320. In other words, the light-shielding layer 310 can adjust the light-emitting angle of the maximum light-emitting viewing angle of the first sub-pixel 200a.

Referring to FIGS. 2 and 5, the minimum distance between the light-shielding layer 310 disposed on the light emission side of the second sub-pixel 200b and the second pixel opening 102b in the second direction X2 is relatively large. Therefore, light emitted by the second sub-pixel 200b in the front viewing-angle direction or the small viewing-angle direction is shielded by the light-shielding layer 310, but light emitted by the second sub-pixel 200b at a large viewing angle is less shielded by the light-shielding layer 310. As such, compared with the first sub-pixel 200a, the second sub-pixel 200b can emit light at a larger viewing angle, thereby enabling the maximum light-emitting viewing angle of the first sub-pixel 200a to be smaller than that of the second sub-pixel 200b. In this case, the first sub-pixel 200a may be regarded as a privacy protection pixel, and the second sub-pixel 200b may be regarded as a sharing pixel. Furthermore, referring to FIG. 4, although the light-shielding layer 310 is disposed on the light emission side of the second sub-pixel 200b, the light emitted by the second sub-pixel 200b at the large viewing angle can be emitted through the light-shielding opening 320. Accordingly, the maximum light-emitting viewing angle of the first sub-pixel 200a is smaller than that of the second sub-pixel 200b. In this case, the first sub-pixel 200a may be regarded as the privacy protection pixel, and the second sub-pixel 200b may be regarded as an auxiliary pixel configured to assist the first sub-pixel 200a in emitting light for display.

It is to be understood that in the embodiments of the present application, the “viewing angle” may refer to an acute angle (such as the angle y shown in FIG. 4) formed between the propagation direction of light emitted by the sub-pixel 200 (such as light z1 in FIG. 4) and the thickness direction of the display panel 10; light at a front viewing angle or at a small viewing angle may refer to light for which an angle between the light-emitting direction of the sub-pixel 200 and the thickness direction of the display panel 10 is relatively small, for example, 0°, 5°, or 10°; light at a large viewing angle may refer to light for which the angle between the light-emitting direction of the sub-pixel 200 and the thickness direction of the display panel 10 is relatively large, for example, 50°, 60°, or 70°. In the embodiments of the present application, the “small viewing angle” and the “large viewing angle” are relative concepts, and no specific numerical limitations are imposed on corresponding angular magnitudes thereof.

Specifically, with continued reference to FIGS. 2 and 4, the light-emitting adjustment structure 300 includes first openings 300a. Along the first direction X1, a first opening 300a that at least partially overlaps the first sub-pixel 200a (which may be understood as the light-shielding opening 320 provided in the light-shielding layer 310) covers the first pixel opening 102a. As such, it is ensured that a large portion of the light emitted by the first sub-pixel 200a can be emitted through the light-shielding opening 320.

With continued reference to FIG. 2, along the first direction X1, a second opening 300b (which may be understood as a break between two adjacent light-shielding layers 310 along the second direction X2) covers the second pixel opening 102b. As such, it is ensured that a large portion of the light emitted by the second sub-pixel 200b can be emitted through the second opening 300b. Moreover, the minimum distance between an edge of the first opening 300a and an edge of the first pixel opening 102a is m1, and the minimum distance between an edge of the second opening 300b and an edge of the second pixel opening 102b is m2, and m1 and m2 satisfy that m2>m1. In other words, the distance between the edge of the first opening 300a and the edge of the first pixel opening 102a is smaller such that light emitted by the first sub-pixel 200a at the front viewing angle or at a relatively small viewing angle can be emitted through the first opening 300a, while light emitted by the first sub-pixel 200a at a relatively large viewing angle can be shielded by the light-shielding layer 310; the distance between the edge of the second opening 300b and the edge of the second pixel opening 102b is larger such that light emitted by the second sub-pixel 200b at a relatively large viewing angle cannot be shielded by the light-shielding layer 310, or only a small portion of light emitted by the second sub-pixel 200b at a relatively large viewing angle can be shielded by the light-shielding layer 310, thereby ensuring that the second sub-pixel 200b can emit light at the large viewing angle. Further, referring to FIG. 4, along the first direction X1, the light-shielding layer 310 covers the second pixel opening 102b such that the light emitted by the second sub-pixel 200b is mainly emitted through the first opening 300a. In other words, the light emitted by the first sub-pixel 200a at the relatively small viewing angle or at the front viewing angle can be emitted through the first opening 300a without being shielded by the light-shielding layer 310 outside the first opening 300a. In contrast, light emitted by the second sub-pixel 200b at a relatively small viewing angle or at a front viewing angle is shielded by the light-shielding layer 310, while the light emitted by the second sub-pixel 200b at the relatively large viewing angle is emitted through the first opening 300a. It is to be noted that the specific values of m1 and m2 are not limited in the embodiments of the present application and may be reasonably set according to the panel size and display resolution.

Specifically, the display modes of the display panel 10 include the sharing display mode and the privacy-protection display mode. In the sharing display mode, both the first sub-pixels 200a and the second sub-pixels 200b emit light, that is, light emission is implemented through the cooperation of the first sub-pixels 200a and the second sub-pixels 200b, such that the entire light emitted by the multiple sub-pixels 200 in the display panel 10 is visible in the front viewing-angle direction (that is, the small viewing-angle direction) and the large viewing-angle direction. In particular, light emitted by the first sub-pixels 200a is visible in the front viewing-angle direction, and light emitted by the second sub-pixels 200b is at least visible in the large viewing-angle direction, thereby enabling normal display at different viewing angles. In the privacy-protection display mode, the first sub-pixels 200a emit light while the second sub-pixels 200b do not emit light such that the entire light emitted by the multiple sub-pixels 200 in the display panel 10 is visible only in the front viewing-angle direction (that is, the small viewing-angle direction). In this manner, light emission in the large viewing-angle direction is absent so that information displayed at the large viewing angle cannot be presented, thereby concealing the information displayed in the large viewing-angle direction and fulfilling the privacy protection function of the display panel 10.

Referring to FIGS. 2 and 4, the first sub-pixel 200a includes the first anode 211 and the first cathode 212 that form the first microcavity structure. Accordingly, the light emitted by the first sub-pixel 200a can be modulated within the first microcavity structure. Specifically, the emission wavelength of the first sub-pixel 200a is λ1, the distance between the first anode 211 and the first cathode 212 along the first direction X1 is L1, and the cavity length L1 of the first microcavity structure along the first direction X1 satisfies that L1=n×(λ1/2). That is, the cavity length of the first microcavity structure is a half-integer multiple of the emission wavelength of the first sub-pixel 200a. In this manner, the first microcavity structure can provide strong microcavity modulation for light transmitted along the first direction X1 in the first sub-pixel 200a, thereby ensuring that light emitted by the first sub-pixel 200a at the front viewing angle can have a strong intensity and high brightness.

Specifically, FIG. 6 is a graph between viewing-angle brightness and a light-emitting viewing angle of a sub-pixel according to the present application. Referring to FIG. 6, FIG. 6 illustrates the graph of the relationship between the viewing-angle brightness of the first sub-pixel 200a and the light-emitting energy of the first sub-pixel 200a. In the figure, the horizontal axis represents the light-emitting viewing angle of the sub-pixel, and the vertical axis represents the light-emitting energy of the sub-pixel, indicating the normalized light-emitting energy. It can be seen from FIG. 6 that the light-emitting brightness of the first sub-pixel 200a at the front viewing angle is higher, and the light-emitting brightness of the first sub-pixel 200a at the large viewing angle is lower.

Further, referring to FIGS. 2, 4, and 5, the second sub-pixel 200b includes the second anode 221 and the second cathode 222 that form the second microcavity structure. Accordingly, the light emitted by the second sub-pixel 200b can be modulated within the second microcavity structure.

Specifically, light generated in the second sub-pixel 200b is transmitted within the second microcavity structure, the emission wavelength of the second sub-pixel 200b is λ2, the distance between the second anode 221 and the second cathode 222 along the first direction X1 is L2, and the cavity length L2 of the second microcavity structure along the first direction X1 satisfies that L2≠n×(λ2/2). In other words, the cavity length of the second microcavity structure does not satisfy a half-integer multiple of the emission wavelength of the second sub-pixel 200b. As a result, the modulation effect on the light at the front viewing angle in the second sub-pixel 200b is weakened. In this case, the resonance condition is no longer a rigid criterion of “being not satisfied means suppression”, but rather becomes a flexible relationship in which “the higher the degree of satisfaction, the stronger the output”. In a weak microcavity structure, the light at the large viewing angle that may be suppressed in the strong microcavity structure can also participate in resonance and be emitted. This effectively expands the selectable range of the light-emitting direction, thereby further broadening the light-emitting viewing angle, also increasing the light-emitting energy of the light at the large viewing angle, and ensuring the light-emitting brightness at the large viewing angle. In one or more embodiments, with reference to FIGS. 2 and 5, FIG. 2 and FIG. 5 may be understood as different configurations of the second sub-pixel 200b provided in FIG. 1. In FIG. 2, only in an edge region of the second sub-pixel 200b, the condition that the distance between the second anode 221 and the second cathode 222 is L2 is satisfied. In FIG. 5, among all the regions of the second sub-pixel 200b, the condition that the distance between the second anode 221 and the second cathode 222 is L2 is satisfied. Accordingly, the configuration of the second sub-pixel 200b is diverse and may be adaptively adjusted according to actual requirements of the display panel 10.

Specifically, referring to FIG. 6, it can be seen that the light-emitting brightness of the second sub-pixel 200b at the large viewing angle is higher, and the light-emitting brightness of the second sub-pixel 200b at the front viewing angle is lower than the light-emitting brightness of the first sub-pixel 200a at the front viewing angle. This demonstrates that the light-emitting brightness of the second sub-pixel 200b at the large viewing angle can be enhanced by adjusting the cavity length of the second microcavity structure along the first direction X1.

In other words, the adjusted cavity length of the first microcavity structure along the first direction X1 in the first sub-pixel 200a satisfies the half-integer multiple of the emission wavelength of the first sub-pixel 200a, so the first microcavity structure may be regarded as a strong microcavity structure. The strong microcavity structure can enhance the light-emitting brightness of the first sub-pixel 200a at the front viewing angle or at the small viewing angle. In contrast, the cavity length of the second microcavity structure along the first direction X1 in the second sub-pixel 200b does not satisfy the half-integer multiple of the emission wavelength of the second sub-pixel 200b, so the second microcavity structure may be regarded as a weak microcavity structure. In this case, the resonance selectivity of the weak microcavity structure is significantly reduced, and the threshold for filtering photons at different angles is lowered such that photons from more directions can satisfy the resonance condition and be emitted. As a result, the light-emitting viewing angle can be broadened, and the light-emitting energy at the large viewing angle can be increased, thereby enhancing the light-emitting brightness of the second sub-pixel 200b at the large viewing angle.

Specifically, referring to FIGS. 2 and 4, the adjustment of the cavity length of the first microcavity structure along the first direction X1 may be implemented by adjusting the number and/or thickness of films of a light-emitting structure between the first anode 211 and the first cathode 212 in the first sub-pixel 200a. No matter whether the first sub-pixel 200a includes a single light-emitting layer or multiple light-emitting layers connected in series, the adjustment can be implemented by adjusting the number and/or thickness of the films of the light-emitting structure between the first anode 211 and the first cathode 212. Similarly, referring to FIGS. 2, 4, and 5, the adjustment of the cavity length of the second microcavity structure along the first direction X1 can be implemented by adjusting the number and/or thickness of films of a light-emitting structure between the second anode 221 and the second cathode 222 in the second sub-pixel 200b. No matter whether the second sub-pixel 200b includes a single light-emitting layer or multiple light-emitting layers connected in series, the adjustment can be implemented by adjusting the number and/or thickness of the films of the light-emitting structure between the second anode 221 and the second cathode 222.

It is to be noted that, to adjust the cavity length of the first microcavity structure of the first sub-pixel 200a and the cavity length of the second microcavity structure of the second sub-pixel 200b at the same time to ensure the overall display performance of the display panel 10, the height of the pixel definition layer 102 between the first sub-pixel 200a and the second sub-pixel 200b can be adjusted, as shown in FIG. 4. In this manner, the overall thickness of the light-emitting structures filled within the pixel openings can be adjusted, thereby adjusting cavity lengths of different microcavity structures and forming the strong microcavity structure in the first sub-pixel 200a and the weak microcavity structure in the second sub-pixel 200b.

In one or more embodiments, the pixel definition layer may also be configured to have a consistent height, and only the overall thickness of the light-emitting structures within the pixel openings is adjusted. As shown in FIG. 2, the cavity length of the second microcavity structure is adjusted by directly adjusting the number and/or thickness of the films of the light-emitting structure in partial regions of the second sub-pixel 200b, thereby forming the weak microcavity structure, and the cavity length of the first microcavity structure is adjusted by directly adjusting the number and/or thickness of the films of the light-emitting structure in the first sub-pixel 200a, thereby forming the strong microcavity structure.

Further, the cavity length of the first microcavity structure along the first direction X1 and the cavity length of the second microcavity structure along the first direction X1 are modulated based on the half-integer multiple of the corresponding emission wavelength. Depending on the adjustment of this multiple, L1 may be greater than L2, or L2 may be greater than L1. FIG. 5 illustrates an example in which L1 is greater than L2. Accordingly, the configurations of the first sub-pixel 200a and the second sub-pixel 200b are diverse. FIGS. 2, 4, and 5 do not exhaustively illustrate specific adjustment manners of the light-emitting structures.

In conclusion, the embodiments of the present application provide the display panel, and the display panel includes the multiple sub-pixels. The multiple sub-pixels include the first sub-pixels and the second sub-pixels that have the same emitted color, and the maximum light-emitting viewing angle of the first sub-pixel is smaller than that of the second sub-pixel. The different display modes of the display panel can be implemented by controlling the light emission of the first sub-pixel and the second sub-pixel. Along the first direction, the distance between the first anode and the first cathode is L1, L1=n×(λ1/2), and λ1 denotes the emission wavelength of the first sub-pixel. That is, the distance of the first microcavity structure along the first direction satisfies the half-integer multiple of the emission wavelength of the first sub-pixel so that a strong microcavity structure can be formed. The strong microcavity structure enhances the light-emitting brightness at the small viewing angle or at the front viewing angle, thereby ensuring the light-emitting performance of the first sub-pixel at the small viewing angle. In the second sub-pixel, the second anode and the second cathode form the second microcavity structure, and along the first direction, the distance between the at least part of the second anode and the at least part of the second cathode is L2, L2≠m×(λ2/2), and λ2 denotes the emission wavelength of the second sub-pixel. That is, the distance of the second microcavity structure along the first direction does not satisfy the half-integer multiple of the emission wavelength of the second sub-pixel so that a weak microcavity structure can be formed. Therefore, in the weak microcavity structure, the light at the large viewing angle that may be suppressed in the strong microcavity structure can also participate in resonance and be emitted, thereby enhancing the light-emitting brightness of the light at the large viewing angle and ensuring the light-emitting performance of the second sub-pixel at the large viewing angle. Further, the display modes of the display panel include the sharing display mode and the privacy-protection display mode. In the sharing display mode, the first sub-pixels and the second sub-pixels emit light, which can ensure the light-emitting performance of the display panel at the large viewing angle and at the front viewing angle, thereby ensuring the overall display performance of the display panel. In the privacy-protection display mode, the first sub-pixels emit light, and the second sub-pixels do not emit light, which can ensure the light-emitting performance of the display panel at the front viewing angle and cause the information displayed at the large viewing angle to be absent, thereby concealing the information displayed in the large viewing-angle direction and fulfilling the privacy protection function of the display panel.

Referring to FIGS. 1, 2, and 5, the second sub-pixel 200b includes a first sub-pixel portion 200b1 and a second sub-pixel portion 200b2, and the first sub-pixel portion 200b1 surrounds at least part of the second sub-pixel portion 200b2. The second anode 221 includes a first anode portion 221a and a second anode portion 221b that are connected, and the second cathode 222 includes a first cathode portion 222a and a second cathode portion 222b that are connected; the first sub-pixel portion 200b1 includes the first anode portion 221a and the first cathode portion 222a, and the second sub-pixel portion 200b2 includes the second anode portion 221b and the second cathode portion 222b. The second microcavity structure includes a first microcavity structure portion formed by the first anode portion 221a and the first cathode portion 222a and a second microcavity structure portion formed by the second anode portion 221b and the second cathode portion 222b; along the first direction X1, the distance at least between the first anode portion 221a and the first cathode portion 222a is L2.

Referring to FIGS. 1, 2, and 5, the second sub-pixel 200b includes the first sub-pixel portion 200b1 and the second sub-pixel portion 200b2, and the first sub-pixel portion 200b1 surrounds the at least part of the second sub-pixel portion 200b2. Accordingly, the first sub-pixel portion 200b1 may be understood as the peripheral portion of the second sub-pixel 200b, and the second sub-pixel portion 200b2 may be understood as the inner portion of the second sub-pixel 200b.

Further, referring to FIGS. 1, 2, and 5, the second anode 221 includes the first anode portion 221a and the second anode portion 221b that are connected, and the second cathode 222 includes the first cathode portion 222a and the second cathode portion 222b that are connected. The first anode portion 221a and the first cathode portion 222a are electrode structures in the first sub-pixel portion 200b1, and the second anode portion 221b and the second cathode portion 222b are electrode structures in the second sub-pixel portion 200b2. The first sub-pixel portion 200b1 is easily distinguished from the second sub-pixel portion 200b2 by partitioning the second anode 221 and the second cathode 222 into different regions.

Further, the second microcavity structure includes the first microcavity structure portion and the second microcavity structure portion. In conjunction with FIGS. 2 and 5, the first anode portion 221a and the first cathode portion 222a form the first microcavity structure portion, and light emitted by the first sub-pixel portion 200b1 is modulated within the first microcavity structure portion; the second anode portion 221b and the second cathode portion 222b form the second microcavity structure portion, and light emitted by the second sub-pixel portion 200b2 is modulated within the second microcavity structure portion.

Further, along the first direction X1, at least the distance between the first anode portion 221a and the first cathode portion 222a is L2. That is, the weak microcavity structure is at least formed between the first anode portion 221a and the first cathode portion 222a in the second sub-pixel 200b. As a feasible embodiment, referring to FIG. 2, the distance between the first anode portion 221a and the first cathode portion 222a in the first microcavity structure portion is L2, while the distance between the second anode portion 221b and the second cathode portion 222b in the second microcavity structure portion is not L2. In this manner, the cavity length of the first microcavity structure portion satisfies the condition of a weak microcavity structure, that is, the first microcavity structure portion can achieve a weak microcavity effect. Moreover, the cavity length of the second microcavity structure portion does not satisfy the condition of a weak microcavity structure; that is, the second microcavity structure portion cannot achieve a weak microcavity effect and may even achieve a strong microcavity effect.

As another feasible embodiment, referring to FIG. 5, in the second sub-pixel 200b, the distance between the entire second anode 221 and the entire second cathode 222 along the first direction X1 is L2. In this manner, a weak microcavity structure is formed between the second anode 221 and the second cathode 222 in any region of the second sub-pixel 200b. In conjunction with FIGS. 2 and 5, in at least part of the second sub-pixel 200b, the light at the large viewing angle that may be suppressed in the strong microcavity structure can also participate in resonance and be emitted in the weak microcavity structure, thereby enhancing the light-emitting brightness of the light at the large viewing angle and further ensuring the light-emitting performance of the second sub-pixel 200b at the large viewing angle.

With continued reference to FIG. 5, along the first direction X1, the distance between the second anode portion 221b and the second cathode portion 222b is L2.

Specifically, referring to FIG. 5, in the second sub-pixel 200b, along the first direction X1, both the distance between the second anode portion 221b and the second cathode portion 222b and the distance between the first anode portion 221a and the first cathode portion 222a are L2. Therefore, the length of the second microcavity structure portion along the first direction X1 does not satisfy a half-integer multiple of the emission wavelength of the second sub-pixel portion 200b2, that is, does not satisfy the half-integer multiple of the emission wavelength of the second sub-pixel 200b. As such, a weak microcavity structure can also be formed, and the light at the large viewing angle that may be suppressed in the strong microcavity structure can also participate in resonance and be emitted in the weak microcavity structure, thereby enhancing the light-emitting brightness of the light at the large viewing angle, ensuring the light-emitting performance of the second sub-pixel portion 200b2 at the large viewing angle, and further ensuring the overall light-emitting performance of the second sub-pixel 200b at the large viewing angle.

Further, referring to FIG. 5, along the first direction X1, the cavity length of the first microcavity structure portion is the same as that of the second microcavity structure portion. In this manner, it can be ensured that the film structure disposed between the first anode portion 221a and the first cathode portion 222a is the same as the film structure disposed between the second anode portion 221b and the second cathode portion 222b. For example, the number and thickness of films disposed between the first anode portion 221a and the first cathode portion 222a can be the same as those between the second anode portion 221b and the second cathode portion 222b. Therefore, the structure of the second sub-pixel 200b can be simplified, and the process preparation cost of the display panel 10 can be reduced. Moreover, the overall flatness of the second anode 221 and the second cathode 222 across their entire surfaces can also be ensured, thereby guaranteeing the overall flatness of the display panel 10.

With continued reference to FIG. 2, along the first direction X1, the distance between the second anode portion 221b and the second cathode portion 222b is L3, L3=p×(λ2/2), and p is a positive integer.

Specifically, referring to FIG. 2, along the first direction X1, the distance between the second anode portion 221b and the second cathode portion 222b is L3, and the cavity length of a microcavity structure formed by the second anode portion 221b and the second cathode portion 222b along the first direction X1 is L3. L3 satisfies that L3=p×(λ2/2), that is, this microcavity structure satisfies the half-integer multiple of the emission wavelength of the second sub-pixel 200b. In this manner, this microcavity structure can provide strong microcavity modulation for part of light transmitted along the first direction X1 in the second sub-pixel 200b, thereby ensuring that part of light emitted at the front viewing angle has a strong intensity and high brightness. Therefore, when the cavity length of the second microcavity structure portion satisfies the half-integer multiple of the emission wavelength of the second sub-pixel 200b, constructive interference can be performed within the second microcavity structure portion on part of the light emitted by the second sub-pixel 200b, thereby enhancing the light-emitting performance of the second sub-pixel 200b at the front viewing angle.

In the second sub-pixel 200b, the first sub-pixel portion 200b1 serves as the peripheral portion of the second sub-pixel 200b. By configuring the cavity length of the first microcavity structure portion not satisfying the half-integer multiple of the emission wavelength of the second sub-pixel 200b, the light-emitting performance of the peripheral region of the second sub-pixel 200b at the large viewing angle can be ensured. In the second sub-pixel 200b, the second sub-pixel portion 200b2 serves as the inner portion of the second sub-pixel 200b. By configuring the cavity length of the second microcavity structure portion satisfying the half-integer multiple of the emission wavelength of the second sub-pixel 200b, the light-emitting performance of the inner region of the second sub-pixel 200b at the front viewing angle can be ensured. Accordingly, by finely tuning the second sub-pixel 200b, the light-emitting performance of the second sub-pixel 200b at multiple angles can be ensured, thereby further ensuring the overall display performance of the display panel 10.

With continued reference to FIGS. 3 and 4, the second sub-pixel 200b surrounds at least part of the first sub-pixel 200a.

Further, referring to FIGS. 3 and 4, the second sub-pixel 200b is disposed to surround part of the first sub-pixel 200a. The light emitted by the first sub-pixel 200a can be emitted at a front viewing angle through an opening in the light-shielding layer 310, and the light emitted by the second sub-pixel 200b can be emitted at a large viewing angle through an opening in the light-shielding layer 310.

Specifically, when the display panel 10 operates in the privacy-protection display mode, the first sub-pixel 200a is controlled to emit light for display, thereby ensuring the light-emitting performance of the display panel 10 at the front viewing angle, while the second sub-pixel 200b does not emit light, so the display of the display panel 10 is absent at the large viewing angle. Therefore, the display information of the display panel 10 can be kept confidential in the large viewing-angle direction, thereby fulfilling the privacy protection function of the display panel 10. When the display panel 10 operates in the sharing display mode, the first sub-pixel 200a is controlled to emit light for display, thereby ensuring the light-emitting performance of the display panel 10 at the front viewing angle, and the second sub-pixel 200b is also controlled to emit light for display to provide compensation for light that is absent from the first sub-pixel 200a at the large viewing angle, thereby ensuring the light-emitting performance of the display panel 10 at the large viewing angle. Therefore, the light-emitting performance of the display panel 10 at various viewing angles can be ensured in the sharing display mode.

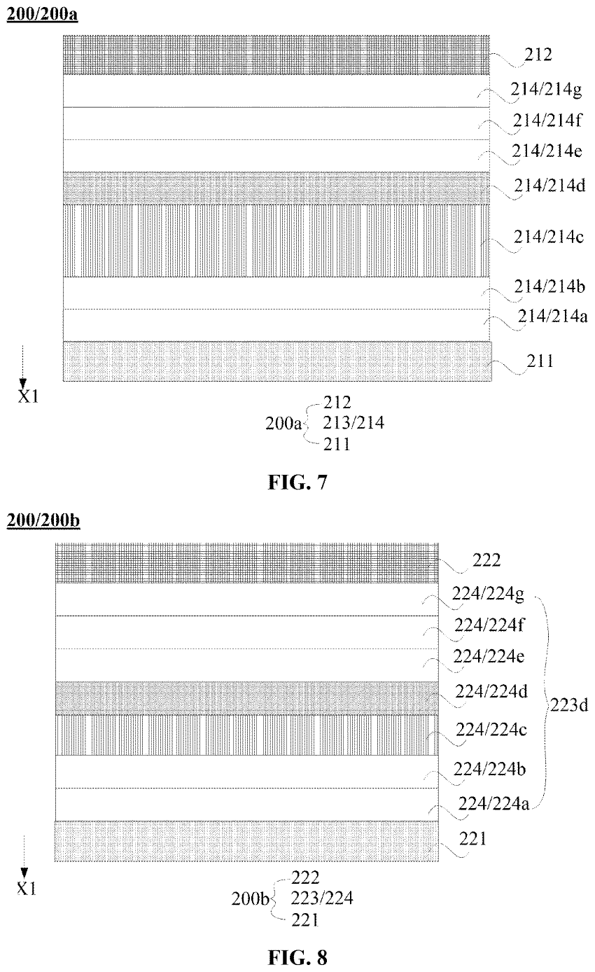

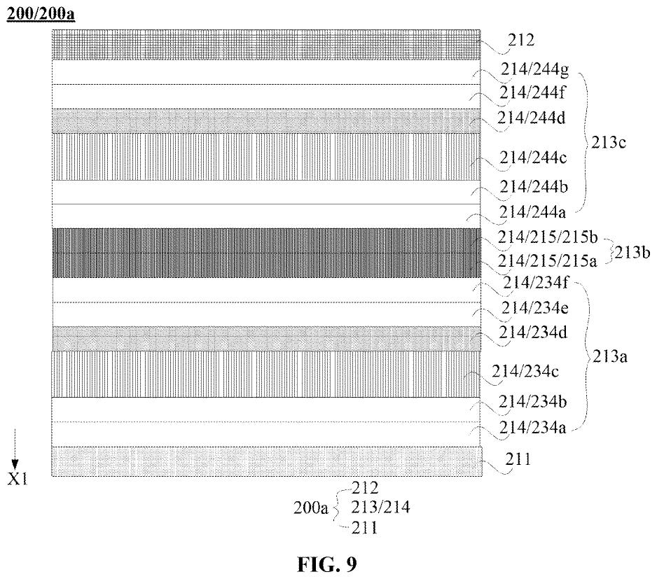

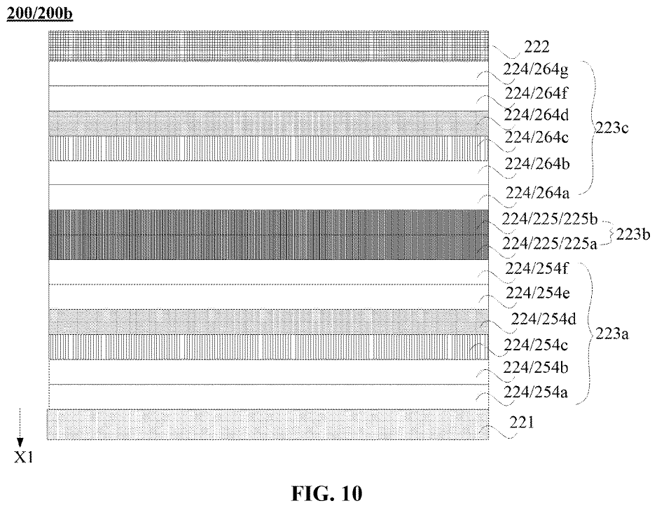

FIG. 7 is an enlarged diagram of a first sub-pixel according to the present application. FIG. 8 is an enlarged diagram of a second sub-pixel according to the present application. FIG. 9 is another enlarged diagram of a first sub-pixel according to the present application. FIG. 10 is another enlarged diagram of a second sub-pixel according to the present application. Referring to FIGS. 7 to 10, the first sub-pixel 200a further includes a first light-emitting structure 213 located between the first anode 211 and the first cathode 212, and the first light-emitting structure 213 includes multiple first light-emitting material layers 214; the second sub-pixel 200b further includes a second light-emitting structure 223 located between the second anode 221 and the second cathode 222, and the second light-emitting structure 223 includes multiple second light-emitting material layers 224. The number of first light-emitting material layers 214 in the first light-emitting structure 213 is different from the number of second light-emitting material layers 224 in at least part of the second light-emitting structure 223, and/or the thickness of at least one first light-emitting material layer 214 is different from the thickness of at least part of at least one second light-emitting material layer 224.

FIGS. 7 to 10 are enlarged diagrams of the sub-pixel 200. The first sub-pixel 200a in FIGS. 2 and 4 may be the first sub-pixel 200a shown in FIG. 7 or 9, and the second sub-pixel 200b in FIGS. 2, 4, and 5 may be the second sub-pixel 200b shown in FIG. 8 or 10. It is to be noted that FIGS. 7 to 10 are used to illustrate the specific structure of the sub-pixel 200, and all possible configurations of the sub-pixel 200 are not enumerated in the present application. Therefore, the structure of the sub-pixel 200 may be adaptively adjusted according to actual requirements.

Specifically, referring to FIGS. 7 and 9, the first sub-pixel 200a further includes the first light-emitting structure 213 located between the first anode 211 and the first cathode 212, and the first light-emitting structure 213 includes multiple first light-emitting material layers 214. Referring to FIGS. 8 and 10, the second sub-pixel 200b further includes the second light-emitting structure 223 located between the second anode 221 and the second cathode 222, and the second light-emitting structure 223 includes multiple second light-emitting material layers 224. Further, the thickness of the first light-emitting structure 213 along the first direction X1 may be understood as the cavity length of the first microcavity structure, and the thickness of the second light-emitting structure 223 along the first direction X1 may be understood as the cavity length of the second microcavity structure. To ensure that the cavity length of the first microcavity structure satisfies the half-integer multiple of the emission wavelength of the first sub-pixel 200a, the number of first light-emitting material layers 214 in the first light-emitting structure 213 may be adjusted, or the film thickness of the first light-emitting material layers 214 in the at least part of the first light-emitting structure 213 may be adjusted. It is to be noted that part of the second light-emitting structure 223, for example, an edge region of the second light-emitting structure 223, may be understood as a region divided along a direction parallel to the plane on which the substrate 100 is located, rather than along a direction perpendicular to the plane on which the substrate 100 is located. Alternatively, the number of first light-emitting material layers 214 in the first light-emitting structure 213 may be understood as the total number of all first light-emitting material layers 214 in the first light-emitting structure 213, and the number of second light-emitting material layers 224 in the at least part of the second light-emitting structure 223 may be understood as the total number of second light-emitting material layers 224 in the at least part of the second light-emitting structure 223. Similarly, to ensure that the cavity length of the second microcavity structure does not satisfy the half-integer multiple of the emission wavelength of the second sub-pixel 200b, the number of second light-emitting material layers 224 in the second light-emitting structure 223 may be adjusted, or the film thicknesses of at least some of the second light-emitting material layers 224 may be adjusted.

Exemplarily, referring to FIG. 7, the multiple first light-emitting material layers 214 in the first sub-pixel 200a may include a hole injection layer (HIL) 214a, a hole transport layer (HTL) 214b, a compensation layer (Prime) 214c, an emitting layer (EML) 214d, a hole blocking layer (HBL) 214e, an electron transport layer (ETL) 214f, and an electron injection layer (EIL) 214g. Similarly, referring to FIG. 8, the multiple second light-emitting material layers 224 in the second sub-pixel 200b may include a hole injection layer (HIL) 224a, a hole transport layer (HTL) 224b, a compensation layer (Prime) 224c, an emitting layer (EML) 224d, a hole blocking layer (HBL) 224e, an electron transport layer (ETL) 224f, and an electron injection layer (EIL) 224g. For example, referring to FIGS. 7 and 8, the thickness of the first light-emitting structure 213 along the first direction X1 may be adjusted by adjusting the compensation layer 214c in the first sub-pixel 200a, and the thickness of the second light-emitting structure 223 along the first direction X1 may be adjusted by adjusting the compensation layer 224c in the second sub-pixel 200b. Further, the thickness of the first light-emitting structure 213 along the first direction X1 may also be adjusted by adjusting other film structures in the first light-emitting material layers 214, and the thickness of the second light-emitting structure 223 along the first direction X1 may also be adjusted by adjusting other film structures in the second light-emitting material layers 224.

Further, referring to FIG. 9, the multiple first light-emitting material layers 214 in the first sub-pixel 200a may include a hole injection layer (HIL) 234a, a hole transport layer (HTL) 234b, a compensation layer (Prime) 234c, an emitting layer (EML) 234d, a hole blocking layer (HBL) 234e, an electron transport layer (ETL) 234f, two charge generation layers 215, a hole injection layer (HIL) 244a, a hole transport layer (HTL) 244b, a compensation layer (Prime) 244c, an emitting layer (EML) 244d, an electron transport layer (ETL) 244f, and an electron injection layer (EIL) 244g. Similarly, referring to FIG. 10, the multiple second light-emitting material layers 224 in the second sub-pixel 200b may include a hole injection layer (HIL) 254a, a hole transport layer (HTL) 254b, a compensation layer (Prime) 254c, an emitting layer (EML) 254d, a hole blocking layer (HBL) 254e, an electron transport layer (ETL) 254f, two charge generation layers 225, a hole injection layer (HIL) 264a, a hole transport layer (HTL) 264b, a compensation layer (Prime) 264c, an emitting layer (EML) 264d, an electron transport layer (ETL) 264f, and an electron injection layer (EIL) 264g. The thickness of the first light-emitting structure 213 along the first direction X1 may be adjusted by adjusting the thickness of any film among the first light-emitting material layers 214, and the thickness of the second light-emitting structure 223 along the first direction X1 may be adjusted by adjusting the thickness of any film among the second light-emitting material layers 224.

Therefore, to achieve a differentiated setting of the cavity lengths of the microcavity structures corresponding to the first sub-pixel 200a and the second sub-pixel 200b in the display panel 10, the thickness of at least one first light-emitting material layer 214 may be adjusted to be different from the thickness of at least part of at least one second light-emitting material layer 224. Further, referring to FIGS. 8 and 9, the number of first light-emitting material layers 214 is adjusted to be different from the number of second light-emitting material layers 224 in the at least part of the second light-emitting structure 223, thereby achieving the differentiated setting of the cavity lengths of the first microcavity structure and the second microcavity structure. In this manner, the light-emitting brightness of the first sub-pixel 200a at the front viewing angle can be ensured, and the light-emitting brightness of the second sub-pixel 200b at the large viewing angle can be ensured.

Referring to FIG. 9, the first sub-pixel 200a further includes a first light-emitting structure 213 located between the first anode 211 and the first cathode 212, and the first light-emitting structure 213 includes a first light-emitting unit layer 213a, a first charge generation layer 213b, and a second light-emitting unit layer 213c that are stacked along the first direction X1. The first light-emitting unit layer 213a, the first charge generation layer 213b, and the second light-emitting unit layer 213c each include multiple first light-emitting material layers 214.

Further, referring to FIG. 9, the first light-emitting structure 213 includes the first light-emitting unit layer 213a, the first charge generation layer 213b, and the second light-emitting unit layer 213c that are stacked along the first direction X1. The first light-emitting unit layer 213a and the second light-emitting unit layer 213c each include multiple first light-emitting material layers 214 and may be each understood as a set of film structures arranged between the first anode 211 and the first cathode 212 for emitting light. The first charge generation layer 213b may be understood as a series-connected film structure for serially connecting the first light-emitting unit layer 213a and the second light-emitting unit layer 213c that are stacked. Therefore, the first sub-pixel 200a may be understood as a sub-pixel including multiple light-emitting layers connected in series, and the display panel 10, in which multiple stacked light-emitting unit layers are used for light emission, is referred to as a tandem display panel (tandem OLED). The tandem display panel can enable the sub-pixels 200 to be driven at the same current density so that the brightness of the display panel 10 can be significantly improved. Thus, the light-emitting brightness of the first sub-pixel 200a can be ensured, and the service life of the first sub-pixel 200a can be prolonged.

Specifically, referring to FIG. 9, the first light-emitting unit layer 213a includes a hole injection layer (HIL) 234a, a hole transport layer (HTL) 234b, a compensation layer (Prime) 234c, an emitting layer (EML) 234d, a hole blocking layer (HBL) 234e, and an electron transport layer (ETL) 234f that are sequentially arranged along the first direction X1, and the second light-emitting unit layer 213c includes a hole injection layer (HIL) 244a, a hole transport layer (HTL) 244b, a compensation layer (Prime) 244c, an emitting layer (EML) 244d, an electron transport layer (ETL) 244f, and an electron injection layer (EIL) 244g that are sequentially arranged along the first direction X1. The first charge generation layer 213b includes an n-type charge generation layer 215a and a p-type charge generation layer 215b that are stacked along the first direction X1. The n-type charge generation layer 215a is configured to generate electrons, and the p-type charge generation layer 215b is configured to generate holes, thereby ensuring that the first light-emitting unit layer 213a and the second light-emitting unit layer 213c can emit light normally. It is to be noted that the types and numbers of first light-emitting material layers 214 specifically included in each of the first light-emitting unit layer 213a, the second light-emitting unit layer 213c, and the first charge generation layer 213b are exemplarily illustrated in FIG. 9 and may be adaptively adjusted according to actual conditions.

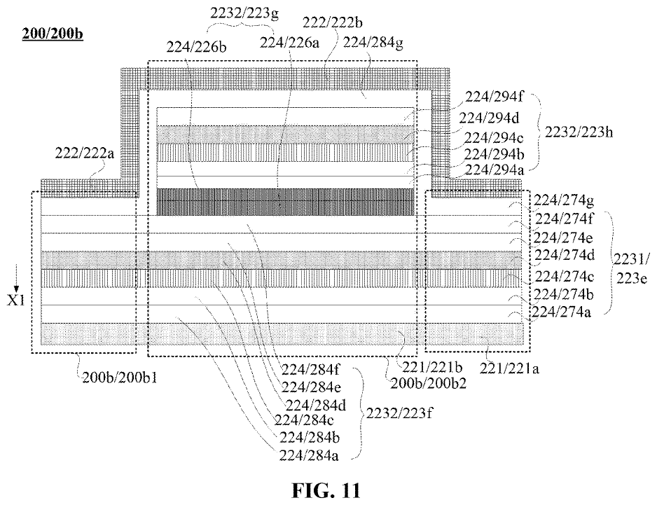

FIG. 11 is another enlarged diagram of a second sub-pixel according to the present application. Referring to FIGS. 8, 10, and 11, the second sub-pixel 200b further includes a second light-emitting structure 223 located between the second anode 221 and the second cathode 222, and the second light-emitting structure 223 includes at least one light-emitting unit layer, and each light-emitting unit layer includes multiple second light-emitting material layers 224.

The second light-emitting structure 223 includes at least one light-emitting unit layer. A light-emitting unit layer may be understood as a set of film structures disposed between the second anode 221 and the second cathode 222 and capable of emitting light. The arrangement of the at least one light-emitting unit layer in the second sub-pixel 200b is diverse. Exemplarily, referring to FIG. 8, one light-emitting unit layer (reference is made to 223d in FIG. 8) may be disposed between the second anode 221 and the second cathode 222; referring to FIG. 10, two light-emitting unit layers (reference is made to 223a and 223c in FIG. 10) may be disposed between the second anode 221 and the second cathode 222; referring to FIG. 11, in one second sub-pixel 200b, one light-emitting unit layer (reference is made to 223e in FIG. 11) may be disposed between part of the second anode 221 and the second cathode 222, and two light-emitting unit layers (reference is made to 223f and 223g in FIG. 11) may be disposed between the other part of the second anode 221 and the second cathode 222.

In one or more embodiments, referring to FIG. 10, the second light-emitting structure 223 includes a third light-emitting unit layer 223a, a second charge generation layer 223b, and a fourth light-emitting unit layer 223c that are stacked along the first direction X1; the third light-emitting unit layer 223a, the second charge generation layer 223b, and the fourth light-emitting unit layer 223c each include multiple second light-emitting material layers 224.

Specifically, referring to FIG. 10, the second light-emitting structure 223 includes the third light-emitting unit layer 223a, the second charge generation layer 223b, and the fourth light-emitting unit layer 223c that are stacked along the first direction X1, and the third light-emitting unit layer 223a and the fourth light-emitting unit layer 223c each include multiple second light-emitting material layers 224 and may be each understood as a set of film structures arranged between the second anode 221 and the second cathode 222 for emitting light. The second charge generation layer 223b may be understood as a series-connected film structure for serially connecting the third light-emitting unit layer 223a and the fourth light-emitting unit layer 223c that are stacked. Therefore, the second sub-pixel 200b may be understood as a sub-pixel including multiple light-emitting layers connected in series, thereby ensuring the light-emitting brightness of the second sub-pixel 200b and prolonging the service life of the second sub-pixel 200b.

Specifically, referring to FIG. 10, the third light-emitting unit layer 223a includes a hole injection layer 254a, a hole transport layer 254b, a compensation layer 254c, an emitting layer 254d, a hole blocking layer 254e, and an electron transport layer 254f that are sequentially arranged along the first direction X1, and the fourth light-emitting unit layer 223c includes a hole injection layer 264a, a hole transport layer 264b, a compensation layer 264c, an emitting layer 264d, an electron transport layer 264f, and an electron injection layer 264g that are sequentially arranged along the first direction X1. The second charge generation layer 223b includes an n-type charge generation layer 225a and a p-type charge generation layer 225b that are stacked along the first direction X1. The n-type charge generation layer 225a is configured to generate electrons, and the p-type charge generation layer 225b is configured to generate holes, thereby ensuring that the third light-emitting unit layer 223a and the fourth light-emitting unit layer 223c can emit light normally. It is to be noted that the types and numbers of second light-emitting material layers 224 specifically included in each of the third light-emitting unit layer 223a, the fourth light-emitting unit layer 223c, and the second charge generation layer 223b are exemplarily illustrated in FIG. 10 and may be adaptively adjusted according to actual conditions.

In one or more embodiments, with continued reference to FIG. 8, the second light-emitting structure 223 includes a fifth light-emitting unit layer 223d, and the fifth light-emitting unit layer 223d includes the multiple second light-emitting material layers 224.

Specifically, referring to FIG. 8, the second light-emitting structure 223 includes the fifth light-emitting unit layer 223d, and the fifth light-emitting unit layer 223d is a set of film structures arranged between the second anode 221 and the second cathode 222 for emitting light. Therefore, the second sub-pixel 200b may be understood as a sub-pixel including one light-emitting layer, which reduces the process preparation difficulty of the second sub-pixel 200b and reduces the process preparation cost of the display panel 10 while ensuring normal light emission of the second sub-pixel 200b. Further, this reflects that the configuration of the second sub-pixel 200b is flexible, and the type of the second sub-pixel 200b may be adaptively adjusted according to actual requirements.

In one or more embodiments, referring to FIG. 11, the second sub-pixel 200b includes a first sub-pixel portion 200b1 and a second sub-pixel portion 200b2, and the first sub-pixel portion 200b1 surrounds at least part of the second sub-pixel portion 200b2; the second anode 221 includes first anode portions 221a and a second anode portion 221b that are connected, and the second cathode 222 includes first cathode portions 222a and a second cathode portion 222b that are connected; a first sub-pixel portion 200b1 includes a first anode portion 221a and a first cathode portion 222a, and the second sub-pixel portion 200b2 includes the second anode portion 221b and the second cathode portion 222b. The first sub-pixel portion 200b1 further includes a first light-emitting structure portion 2231 located between the first anode portion 221a and the first cathode portion 222a, and the second sub-pixel portion 200b2 further includes a second light-emitting structure portion 2232 located between the second anode portion 221b and the second cathode portion 222b. The first light-emitting structure portion 2231 includes a sixth light-emitting unit layer 223e, and the second light-emitting structure portion 2232 includes a seventh light-emitting unit layer 223f, a third charge generation layer 223g, and an eighth light-emitting unit layer 223h that are stacked along the first direction X1. The sixth light-emitting unit layer 223e, the seventh light-emitting unit layer 223f, the third charge generation layer 223g, and the eighth light-emitting unit layer 223h each include multiple second light-emitting material layers 224.

Further, referring to FIG. 11, the second sub-pixel 200b includes the first sub-pixel portion 200b1 and the second sub-pixel portion 200b2. The first sub-pixel portion 200b1 may be understood as the peripheral portion of the second sub-pixel 200b, and the second sub-pixel portion 200b2 may be understood as the inner portion of the second sub-pixel 200b. Specifically, referring to FIG. 11, the second anode 221 includes the first anode portions 221a and the second anode portion 221b that are connected, and the second cathode 222 includes the first cathode portions 222a and the second cathode portion 222b that are connected. The first sub-pixel portion 200b1 includes the first anode portion 221a, the first cathode portion 222a, and the first light-emitting structure portion 2231 located between the first anode portion 221a and the first cathode portion 222a. The second sub-pixel portion 200b2 includes the second anode portion 221b, the second cathode portion 222b, and the second light-emitting structure portion 2232 located between the second anode portion 221b and the second cathode portion 222b.

Further, referring to FIG. 11, the first light-emitting structure portion 2231 includes the sixth light-emitting unit layer 223e, and the sixth light-emitting unit layer 223e may be a set of film structures arranged between the first anode portion 221a and the first cathode portion 222a for emitting light. Therefore, the first sub-pixel portion 200b1 may be understood as a sub-pixel including one light-emitting layer. Referring to FIG. 11, the second light-emitting structure portion 2232 includes the seventh light-emitting unit layer 223f, the third charge generation layer 223g, and the eighth light-emitting unit layer 223h that are stacked along the first direction X1, and the seventh light-emitting unit layer 223f, the third charge generation layer 223g, and the eighth light-emitting unit layer 223h each include multiple second light-emitting material layers 224. The eighth light-emitting unit layer 223h and the seventh light-emitting unit layer 223f may be film structures arranged between the second anode portion 221b and the second cathode portion 222b for emitting light independently. Therefore, the second sub-pixel portion 200b2 may be understood as a sub-pixel including multiple light-emitting layers connected in series. In other words, the peripheral portion in the second sub-pixel 200b may be a sub-pixel including a single light-emitting layer, and the inner portion in the second sub-pixel 200b may be a sub-pixel including multiple light-emitting layers connected in series. The area of the second sub-pixel portion 200b2 may be larger than the area of the first sub-pixel portion 200b1; that is, the area of the inner portion may be larger than the area of the peripheral portion. By configuring the larger-area second sub-pixel portion 200b2 as a series-connected sub-pixel, the overall light-emitting performance of the second sub-pixel 200b can be ensured, the service life of the second sub-pixel 200b can be prolonged, and a strong microcavity effect can be achieved in the inner portion of the second sub-pixel 200b, thereby emitting light at the front viewing angle. By configuring the smaller-area first sub-pixel portion 200b1 as a sub-pixel including a single light-emitting layer, a weak microcavity effect can be achieved in the peripheral portion of the second sub-pixel 200b, thereby achieving light emission at the large viewing angle. Moreover, configuring the first sub-pixel portion 200b1 as the sub-pixel including a single light-emitting layer and the second sub-pixel portion 200b2 as the series-connected sub-pixel further reflects the flexibility in the configuration of the second sub-pixel 200b.

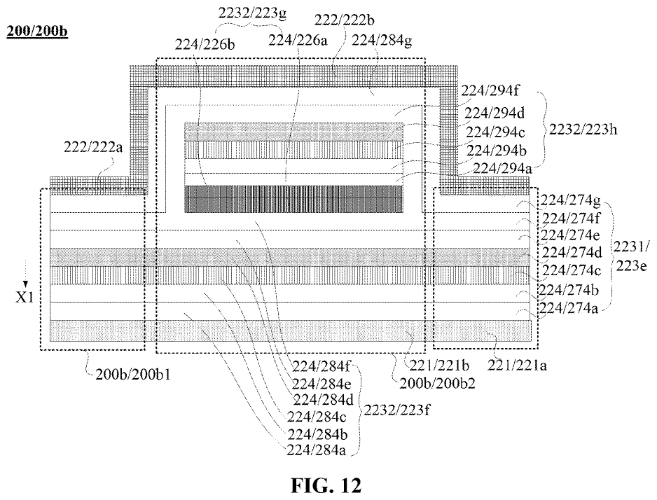

FIG. 12 is another enlarged diagram of a second sub-pixel according to the present application. In one or more embodiments, the sixth light-emitting unit layer 223e may include a first hole injection layer 274a, a first hole transport layer 274b, a first emitting layer 274d, a first electron transport layer 274f, and a first electron injection layer 274g that are stacked along the first direction X1; the seventh light-emitting unit layer 223f may include a second hole injection layer 284a, a second hole transport layer 284b, a second emitting layer 284d, and a second electron transport layer 284f that are stacked along the first direction X1; the third charge generation layer 223g may include an n-type charge generation layer 226a and a p-type charge generation layer 226b that are stacked along the first direction X1; and the eighth light-emitting unit layer 223h may include a third emitting layer 294d, a third electron transport layer 294f, and a second electron injection layer 284g that are stacked along the first direction X1. The first hole injection layer 274a is disposed in the same layer as the second hole injection layer 284a, the first hole transport layer 274b is disposed in the same layer as the second hole transport layer 284b, the first emitting layer 274d is disposed in the same layer as the second emitting layer 284d, the first electron transport layer 274f is disposed in the same layer as the second electron transport layer 284f or the third electron transport layer 294f, and the first electron injection layer 274g is disposed in the same layer as the second electron injection layer 284g.

Further, referring to FIGS. 11 and 12, the sixth light-emitting unit layer 223e includes multiple second light-emitting material layers 224, for example, the first hole injection layer (HIL) 274a, the first hole transport layer (HTL) 274b, the first compensation layer (Prime) 274c, the first emitting layer (EML) 274d, the first hole blocking layer (HBL) 274e, the first electron transport layer (ETL) 274f, the first electron injection layer (EIL) 274g, and other layers that are stacked along the first direction X1. The multiple second light-emitting material layers 224 in the sixth light-emitting unit layer 223e are exemplified in FIGS. 11 and 12, and the types and number of second light-emitting material layers 224 may be adaptively adjusted according to actual requirements.

Further, referring to FIGS. 11 and 12, the seventh light-emitting unit layer 223f includes multiple second light-emitting material layers 224, for example, the second hole injection layer (HIL) 284a, the second hole transport layer (HTL) 284b, the second compensation layer (Prime) 284c, the second emitting layer (EML) 284d, the second hole blocking layer (HBL) 284e, the second electron transport layer (ETL) 284f, and other layers that are stacked along the first direction X1. The multiple second light-emitting material layers 224 in the seventh light-emitting unit layer 223f are exemplified in FIGS. 11 and 12, and the types and number of second light-emitting material layers 224 may be adaptively adjusted according to actual requirements.

Further, referring to FIGS. 11 and 12, the eight light-emitting unit layer 223h includes multiple second light-emitting material layers 224, for example, the third hole injection layer (HIL) 294a, the third hole transport layer (HTL) 294b, the third compensation layer (Prime) 294c, the third emitting layer (EML) 294d, the third electron transport layer (ETL) 294f, the second electron injection layer (EIL) 284g, and other layers that are stacked along the first direction X1. The multiple second light-emitting material layers 224 in the eight light-emitting unit layer 223h are exemplified in FIGS. 11 and 12, and the types and number of second light-emitting material layers 224 may be adaptively adjusted according to actual requirements. The third charge generation layer 223g located between the seventh light-emitting unit layer 223f and the eighth light-emitting unit layer 223h along the first direction X1 includes the n-type charge generation layer 226a and the p-type charge generation layer 226b that are stacked along the first direction X1.

Referring to FIGS. 11 and 12, the first hole injection layer (HIL) 274a and the second hole injection layer (HIL) 284a are disposed in the same layer, the first hole transport layer (HTL) 274b and the second hole transport layer (HTL) 284b are disposed in the same layer, and the first emitting layer (EML) 274d and the second emitting layer (EML) 284d are disposed in the same layer. That is, at least part of the second light-emitting material layers 224 in the sixth light-emitting unit layer 223e is disposed in the same layer as at least part of the second light-emitting material layers 224 in the seventh light-emitting unit layer 223f. In other words, part of the second light-emitting material layers 224 disposed in the same layer is used to form the film structures of the sub-pixel including a single light-emitting layer, and the other part of the second light-emitting material layers 224 disposed in the same layer is used to form the sub-pixel including multiple light-emitting layers connected in series, thereby improving the utilization rate of the second light-emitting material layers 224, enabling flexible configuration of the second sub-pixel 200b, and reducing the overall process difficulty of the display panel 10. Furthermore, referring to FIG. 11, the first electron injection layer (EIL) 274g and the second electron injection layer (EIL) 284g are disposed in the same layer; referring to FIG. 12, the first electron injection layer (EIL) 274g and the second electron injection layer (EIL) 284g are disposed in the same layer, and the first electron transport layer (ETL) 274f, the second electron transport layer (ETL) 284f, and the third electron transport layer (ETL) 294f are also disposed in the same layer, which further reflects the flexibility in the configuration of the second sub-pixel 200b.

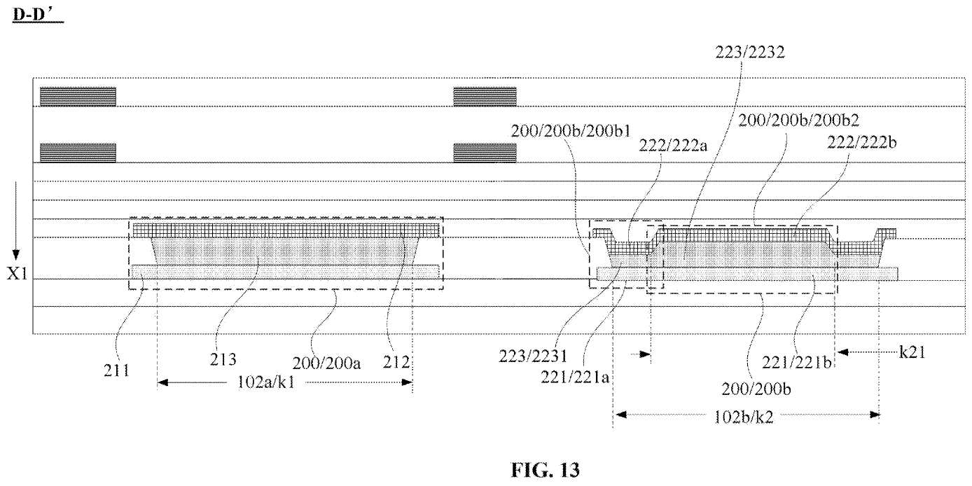

FIG. 13 is a cross-sectional view taken along D-D′ of FIG. 1. Referring to FIGS. 1 and 13, the opening area of the second sub-pixel 200b is greater than or equal to the opening area of the first sub-pixel 200a, and the opening area of the second sub-pixel portion 200b2 is smaller than the opening area of the first sub-pixel 200a.

Referring to FIG. 13, the opening area may be understood as the opening area of a pixel opening of the pixel definition layer 102, and the pixel opening is used to define at least part of the light-emitting region of the first sub-pixel 200a. Specifically, when the opening area of the second sub-pixel 200b is equal to the opening area of the first sub-pixel 200a, the overall structural regularity of the display panel 10 can be ensured, the preparation difficulty of the pixel definition layer 102 can be reduced, and the process cost of the display panel 10 can be lowered. Further, the first sub-pixel 200a disposed in the display panel 10 can ensure the light-emitting brightness at the front viewing angle, and the second sub-pixel 200b disposed in the display panel 10 can ensure the light-emitting brightness at the front viewing angle and at the large viewing angle. To ensure the light-emitting performance at various viewing angles, corresponding pixel openings may be adaptively adjusted. Specifically, the opening area of the second sub-pixel 200b is adjusted to be larger than the opening area of the first sub-pixel 200a so that the light-emitting brightness at both the front viewing angle and the large viewing angle can be taken into account, thereby ensuring that the display panel has high display performance at various viewing angles. It is to be noted that, as shown in FIG. 1, the pixel opening of the sub-pixel may be circular such that the shape of the pixel opening can be regular, and optical diffraction caused by a sharp angle can be avoided, thereby improving the light-emitting performance and display performance of the display panel. Moreover, the opening area of the second sub-pixel 200b is greater than or equal to the opening area of the first sub-pixel 200a. FIG. 13 exemplifies that the opening width (or diameter) of the second sub-pixel 200b in the second direction is k2, and the opening width (or diameter) of the first sub-pixel 200a in the second direction is k1, where k2≥k1. FIG. 13 illustrates the relationship between the opening areas of the pixel openings through the relationship between the opening widths (diameters) of the pixel openings.

Further, in the case where the opening area of the second sub-pixel 200b is larger than that of the first sub-pixel 200a, to ensure sufficient display brightness of the first sub-pixel 200a at the front viewing angle in the sharing display mode and the privacy-protection display mode, it is necessary to ensure that the opening area of the first sub-pixel 200a is not too small. Specifically, the opening area of the first sub-pixel 200a may be set to be larger than that of the second sub-pixel portion 200b2; that is, the opening area of the first sub-pixel 200a is larger than the opening area of the inner portion of the second sub-pixel 200b, thereby ensuring that the first sub-pixel 200a has sufficient display brightness at the front viewing angle. It is to be noted that FIG. 13 exemplifies that the opening width (or diameter) of the first sub-pixel 200a in the second direction is k1, and the opening width (or diameter) of the second sub-pixel portion 200b2 in the second direction is k21, where k1>k21. FIG. 13 illustrates the relationship between the opening areas of the pixel openings through the relationship between the opening widths (diameters) of the pixel openings.

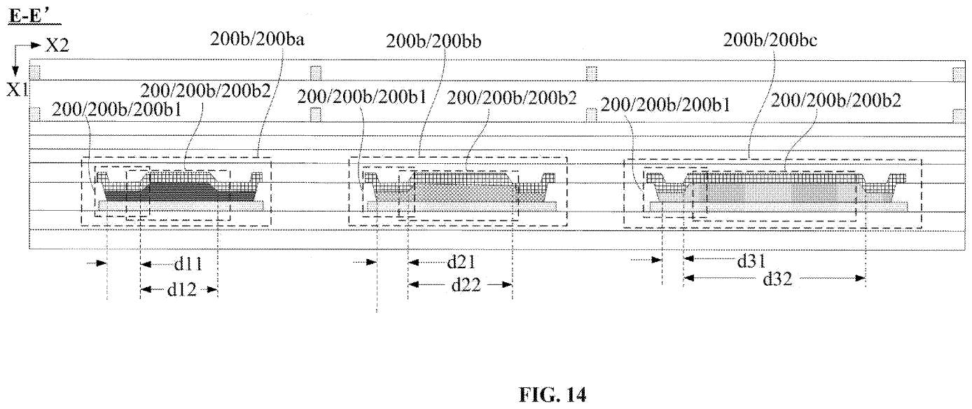

FIG. 14 is a cross-sectional view taken along E-E′ of FIG. 1. Referring to FIGS. 1 and 14, the second sub-pixels 200b include a first-color second sub-pixel 200ba, a second-color second sub-pixel 200bb, and a third-color second sub-pixel 200bc; the luminescence efficiency of the first-color second sub-pixel 200ba is higher than the luminescence efficiency of the second-color second sub-pixel 200bb, and the luminescence efficiency of the second-color second sub-pixel 200bb is higher than the luminescence efficiency of the third-color second sub-pixel 200bc. In the first-color second sub-pixel 200ba, the length of the first sub-pixel portion 200b1 located on one side of the second sub-pixel portion 200b2 in the second direction X2 is d11, and the length of the second sub-pixel portion 200b2 in the second direction X2 is d12; in the second-color second sub-pixel 200bb, the length of the first sub-pixel portion 200b1 located on one side of the second sub-pixel portion 200b2 in the second direction X2 is d21, and the length of the second sub-pixel portion 200b2 in the second direction X2 is d22; in the third-color second sub-pixel 200bc, the length of the first sub-pixel portion 200b1 located on one side of the second sub-pixel portion 200b2 in the second direction X2 is d31, and the length of the second sub-pixel portion 200b2 in the second direction X2 is d32, where the second direction X2 is parallel to the plane on which the substrate 100 is located. d11/d12>d21/d22>d31/d32.

Specifically, referring to FIGS. 1 and 14, the second sub-pixels 200b include the first-color second sub-pixel 200ba, the second-color second sub-pixel 200bb, and the third-color second sub-pixel 200bc. The first-color second sub-pixel 200ba, the second-color second sub-pixel 200bb, and the third-color second sub-pixel 200bc have different emitted colors to enable the color display performance of the display panel 10. The second sub-pixels 200b of different colors have different luminescence efficiencies. The luminescence efficiency of the first-color second sub-pixel 200ba is higher than that of the second-color second sub-pixel 200bb, and the luminescence efficiency of the second-color second sub-pixel 200bb is higher than that of the third-color second sub-pixel 200bc. Exemplarily, the first-color second sub-pixel 200ba may be a second sub-pixel 200b that emits green light, the second-color second sub-pixel 200bb may be a second sub-pixel 200b that emits red light, and the third-color second sub-pixel 200bc may be a second sub-pixel 200b that emits blue light.

Further, the second sub-pixels 200b may be finely adjusted according to different luminescence efficiencies of second sub-pixels 200b. Specifically, referring to FIG. 14, in the first-color second sub-pixel 200ba, the length of the first sub-pixel portion 200b1 located on the side of the second sub-pixel portion 200b2 in the second direction X2 is d11, and the length of the second sub-pixel portion 200b2 in the second direction X2 is d12, where d11/d12 may be understood as the length ratio of the first sub-pixel portion 200b1 to the second sub-pixel portion 200b2 in the first-color second sub-pixel 200ba and may also be understood as the area ratio of the first sub-pixel portion 200b1 to the second sub-pixel portion 200b2 in the first-color second sub-pixel 200ba. Similarly, referring to FIG. 14, in the second-color second sub-pixel 200bb, the length of the first sub-pixel portion 200b1 located on the side of the second sub-pixel portion 200b2 in the second direction X2 is d21, and the length of the second sub-pixel portion 200b2 in the second direction X2 is d22, where d21/d22 may be understood as the length ratio of the first sub-pixel portion 200b1 to the second sub-pixel portion 200b2 in the second-color second sub-pixel 200bb and may also be understood as the area ratio of the first sub-pixel portion 200b1 to the second sub-pixel portion 200b2 in the second-color second sub-pixel 200bb. Similarly, referring to FIG. 14, in the third-color second sub-pixel 200bc, the length of the first sub-pixel portion 200b1 located on the side of the second sub-pixel portion 200b2 in the second direction X2 is d31, and the length of the second sub-pixel portion 200b2 in the second direction X2 is d32, where d31/d32 may be understood as the length ratio of the first sub-pixel portion 200b1 to the second sub-pixel portion 200b2 in the third-color second sub-pixel 200bc and may also be understood as the area ratio of the first sub-pixel portion 200b1 to the second sub-pixel portion 200b2 in the third-color second sub-pixel 200bc.

Further, referring to FIG. 14, since the luminescence efficiency of the first-color second sub-pixel 200ba is higher than that of the second-color second sub-pixel 200bb, d11/d12 is adjusted to be greater than d21/d22. In this manner, compared with the second-color second sub-pixel 200bb, in the first-color second sub-pixel 200ba having a higher luminescence efficiency, the second sub-pixel portion 200b2 has a smaller occupied area while the first sub-pixel portion 200b1 has a larger occupied area, thereby ensuring the overall light-emitting balance of the display panel 10 and improving the overall display performance of the display panel 10. Similarly, since the luminescence efficiency of the second-color second sub-pixel 200bb is higher than that of the third-color second sub-pixel 200bc, d21/d22 is adjusted to be greater than d31/d32. In this manner, compared with the third-color second sub-pixel 200bc, in the second-color second sub-pixel 200bb having a higher luminescence efficiency, the second sub-pixel portion 200b2 has a smaller occupied area while the first sub-pixel portion 200b1 has a larger occupied area, thereby ensuring the overall light-emitting balance of the display panel 10 and improving the overall display performance of the display panel 10.

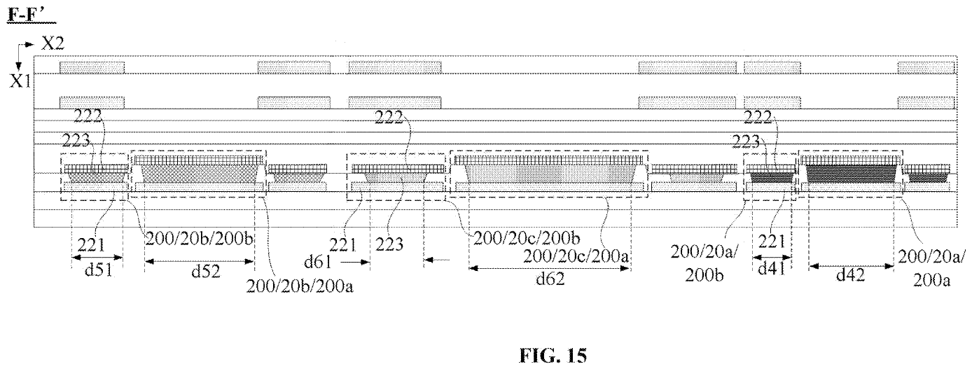

FIG. 15 is a cross-sectional view taken along F-F′ of FIG. 3. Referring to FIGS. 3 and 15, the second sub-pixel 200b further includes a second light-emitting structure 223 located between the second anode 221 and the second cathode 222, and the second light-emitting structure 223 includes a single light-emitting unit layer. The display panel 10 further includes a first-color sub-pixel 20a, a second-color sub-pixel 20b, and a third-color sub-pixel 20c. The luminescence efficiency of the first-color sub-pixel 20a is higher than the luminescence efficiency of the second-color sub-pixel 20b, and the luminescence efficiency of the second-color sub-pixel 20b is higher than the luminescence efficiency of the third-color sub-pixel 20c. In the first-color sub-pixel 20a, the length of the second sub-pixel 200b located on one side of the first sub-pixel 200a in the second direction X2 is d41, and the length of the first sub-pixel 200a in the second direction X2 is d42; in the second-color sub-pixel 20b, the length of the second sub-pixel 200b located on one side of the first sub-pixel 200a in the second direction X2 is d51, and the length of the first sub-pixel 200a in the second direction X2 is d52; in the third-color sub-pixel 20c, the length of the second sub-pixel 200b located on one side of the first sub-pixel 200a in the second direction X2 is d61, and the length of the first sub-pixel 200a in the second direction X2 is d62, where the second direction X2 is parallel to the plane on which the substrate is located. d41/d42>d51/d52>d61/d62.

Specifically, referring to FIGS. 3 and 15, the display panel 10 further includes the first-color sub-pixel 20a, the second-color sub-pixel 20b, and the third-color sub-pixel 20c. The first-color sub-pixel 20a, the second-color sub-pixel 20b, and the third-color sub-pixel 20c have different emitted colors, thereby enabling the overall color display performance of the display panel 10. The sub-pixels 200 of different colors have different luminescence efficiencies. The luminescence efficiency of the first-color sub-pixel 20a is higher than that of the second-color sub-pixel 20b, and the luminescence efficiency of the second-color sub-pixel 20b is higher than that of the third-color sub-pixel 20c. Exemplarily, the first-color sub-pixel 20a may be a green sub-pixel, the second-color sub-pixel 20b may be a red sub-pixel, and the third-color sub-pixel 20c may be a blue sub-pixel.

Further, referring to FIG. 15, in the first-color sub-pixel 20a, the length of the second sub-pixel 200b located on the side of the first sub-pixel 200a in the second direction X2 is d41, and the length of the first sub-pixel 200a in the second direction X2 is d42, where d41/d42 may be used for reflecting the spatial ratio of the first sub-pixel 200a in the first-color sub-pixel 20a and the spatial ratio of the second sub-pixel 200b in the first-color sub-pixel 20a, and a larger value of d41/d42 indicates a larger spatial ratio of the second sub-pixel 200b. Similarly, referring to FIG. 15, in the second-color sub-pixel 20b, the length of the second sub-pixel 200b located on the side of the first sub-pixel 200a in the second direction X2 is d51, and the length of the first sub-pixel 200a in the second direction X2 is d52, where d51/d52 may be used for reflecting the spatial ratio of the first sub-pixel 200a in the second-color sub-pixel 20b and the spatial ratio of the second sub-pixel 200b in the second-color sub-pixel 20b, and a larger value of d51/d52 indicates a larger spatial ratio of the second sub-pixel 200b. Similarly, referring to FIG. 15, in the third-color sub-pixel 20c, the length of the second sub-pixel 200b located on the side of the first sub-pixel 200a in the second direction X2 is d61, and the length of the first sub-pixel 200a in the second direction X2 is d62, where d61/d62 may be used for reflecting the spatial ratio of the first sub-pixel 200a in the third-color sub-pixel 20c and the spatial ratio of the second sub-pixel 200b in the third-color sub-pixel 20c, and a larger value of d61/d62 indicates a larger spatial ratio of the second sub-pixel 200b.

Further, the sub-pixels 200 can be finely adjusted according to different luminescence efficiencies of the sub-pixels 200. Specifically, since the luminescence efficiency of the first-color sub-pixel 20a is higher than that of the second-color sub-pixel 20b, d41/d42 can be adjusted to be greater than d51/d52, that is, in the first-color sub-pixel 20a having a higher luminescence efficiency, the area ratio of the first sub-pixel 200a is higher while the area ratio of the second sub-pixel 200b is lower, thereby balancing the overall display performance of the display panel 10. Similarly, since the luminescence efficiency of the second-color sub-pixel 20b is higher than that of the third-color sub-pixel 20c, d51/d52 can be adjusted to be greater than d61/d62, that is, in the second-color sub-pixel 20b having a higher luminescence efficiency, the area ratio of the first sub-pixel 200a is higher while the area ratio of the second sub-pixel 200b is lower, thereby balancing the overall display performance of the display panel 10. In other words, in combination with the first sub-pixel 200a for ensuring light emission at the front viewing angle and the second sub-pixel 200b for ensuring light emission at the large viewing angle, the occupied areas of the first sub-pixel 200a and the second sub-pixel 200b in the sub-pixels 200 having different luminescence efficiencies are adaptively adjusted, thereby improving the overall display performance of the display panel 10.

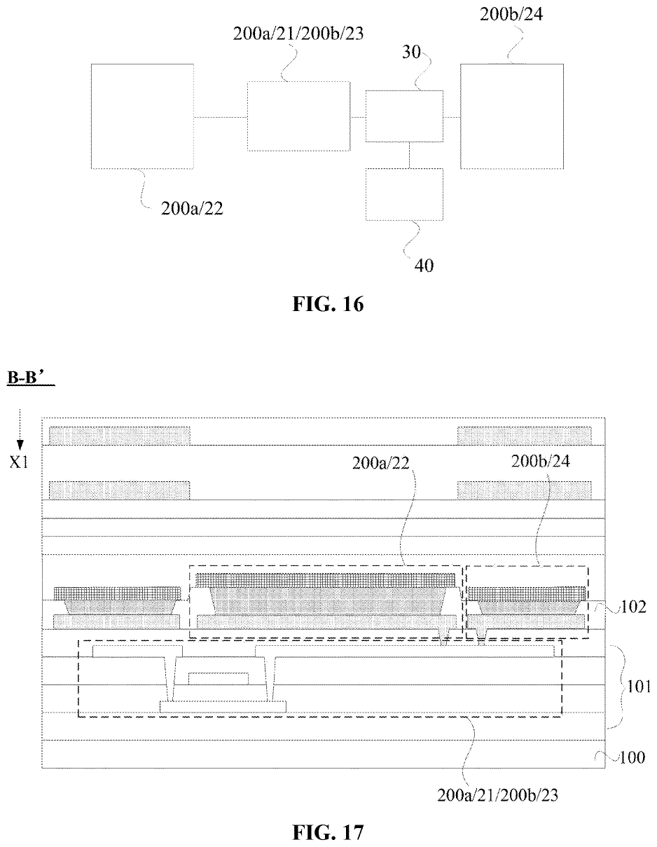

FIG. 16 is a diagram illustrating the connection of a first pixel circuit with a first sub-pixel and a second sub-pixel according to an embodiment of the present application. FIG. 17 is another cross-sectional view taken along B-B′ of FIG. 3. Referring to FIGS. 16 and 17, the first sub-pixel 200a includes a first pixel circuit 21 and a first light-emitting element 22 electrically connected to each other, and the second sub-pixel 200b includes a second pixel circuit 23 and a second light-emitting element 24 electrically connected to each other; and the first pixel circuit 21 also serves as the second pixel circuit 23. The display panel 10 further includes a switch unit 30 and a control module 40, the switch unit 30 is connected in series between the second pixel circuit 23 and the second light-emitting element 24, and the control module 40 is electrically connected to the switch unit 30; the control module 40 is configured to control the switch unit 30 to be turned on in the sharing display mode, to turn on the second pixel circuit 23 and the second light-emitting element 24; and the control module 40 is further configured to control the switch unit 30 to be turned off in the privacy-protection display mode, to turn off the second pixel circuit 23 and the second light-emitting element 24.

Specifically, referring to FIGS. 16 and 17, the first sub-pixel 200a includes the first pixel circuit 21 and the first light-emitting element 22 electrically connected to each other. When being turned on, the first pixel circuit 21 may drive the first light-emitting element 22 to emit light for display, thereby implementing light emission and display of the first sub-pixel 200a. Referring to FIGS. 16 and 17, the second sub-pixel 200b includes the second pixel circuit 23 and the second light-emitting element 24 electrically connected to each other. When being turned on, the second pixel circuit 23 may drive the second light-emitting element 24 to emit light for display, thereby implementing light emission and display of the second sub-pixel 200b. It is to be noted that a pixel circuit may have a “2T1C” structure, a “6T2C” structure, a “7T1C” structure, or an “8T1C” structure, where “T” represents a transistor, and “C” represents a capacitor. The specific structure of the pixel circuit is not limited in the embodiments of the present application. In FIG. 17, the pixel circuit is illustrated by the shown transistors.

Further, referring to FIGS. 16 and 17, since the second light-emitting element 24 surrounds at least part of the first light-emitting element 22 and is used to provide compensation for light emitted by the first light-emitting element 22 at the large viewing angle, and the distance between the first light-emitting element 22 and the second light-emitting element 24 is relatively small, the first light-emitting element 22 and the second light-emitting element 24 may be configured to share one pixel circuit, for example, the first pixel circuit 21. In this manner, it is not necessary to provide an additional pixel circuit for the second light-emitting element 24, thereby ensuring a simple configuration of the pixel circuit in the display panel 10. Moreover, in the privacy-protection display mode, the first light-emitting element 22 emits light while the second light-emitting element 24 does not emit light, that is, the light emission stages of the first light-emitting element 22 and the second light-emitting element 24 are different. Therefore, the switch unit 30 may be disposed between the first pixel circuit 21 and the second light-emitting element 24, and the light emission of the first light-emitting element 22 and the second light-emitting element 24 can be controlled by controlling the switch unit 30 to be turned on or off.

Specifically, referring to FIGS. 16 and 17, the control module 40 is configured to control the switch unit 30 to be turned on in the sharing display mode, to turn on the second pixel circuit 23 and the second light-emitting element 24, thereby enabling the first light-emitting element 22 and the second light-emitting element 24 to emit light for display. The control module 40 is further configured to control the switch unit 30 to be turned off in the privacy-protection display mode, to turn off the second pixel circuit 23 and the second light-emitting element 24, thereby enabling the first light-emitting element 22 to emit light for display and the second light-emitting element 24 not to emit light for display.

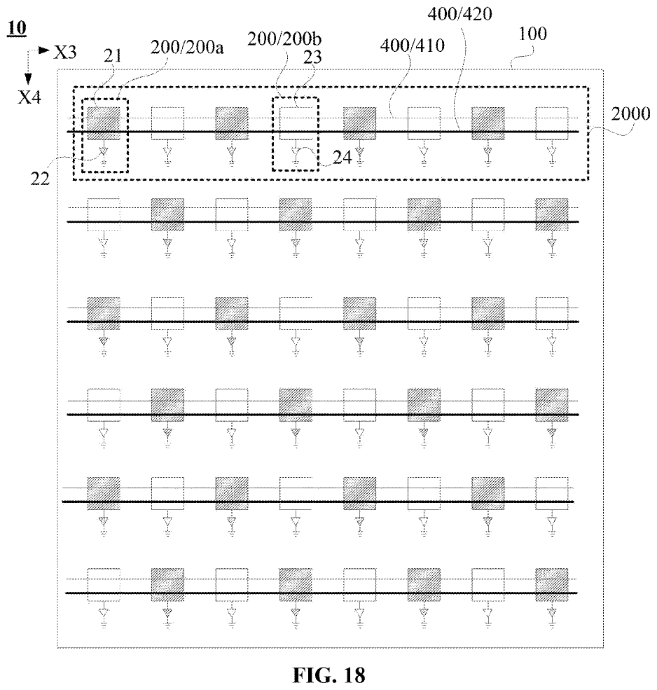

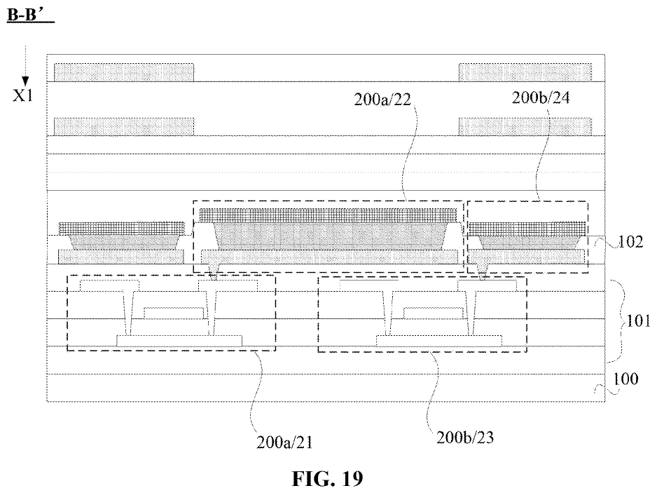

FIG. 18 is another diagram illustrating the structure of a display panel according to an embodiment of the present application. FIG. 19 is another cross-sectional view taken along B-B′ of FIG. 3. Referring to FIGS. 18 and 19, the display panel 10 further includes multiple sub-pixel rows 2000. A sub-pixel row 2000 includes multiple first sub-pixels 200a arranged along the third direction X3 and multiple second sub-pixels 200b arranged along the third direction X3, and the multiple sub-pixel rows 2000 are arranged along the fourth direction X4. The third direction X3 and the fourth direction X4 intersect and are parallel to the plane on which the substrate 100 is located. The first sub-pixel 200a includes a first pixel circuit 21 and a first light-emitting element 22 electrically connected to each other, the second sub-pixel 200b includes a second pixel circuit 23 and a second light-emitting element 24 electrically connected to each other, and the first pixel circuit 21 and the second pixel circuit 23 are independent of each other. In the same sub-pixel row 2000, first pixel circuits 21 and second pixel circuits 23 are arranged along the third direction X3. Moreover, the display panel 10 further includes multiple scan signal lines 400, and the multiple scan signal lines 400 include a first scan signal line 410 and a second scan signal line 420. The first scan signal line 410 and the second scan signal line 420 extend along the third direction X3 and are arranged along the fourth direction X4. Among the first pixel circuits 21 and the second pixel circuits 23 in the same sub-pixel row 2000, the first pixel circuits 21 are electrically connected to the first scan signal line 410, and the second pixel circuits 23 are electrically connected to the second scan signal line 420. In the sharing display mode, a scan signal in the first scan signal line 410 controls the first pixel circuits 21 to be turned on to control first light-emitting elements 22 to emit light, and a scan signal in the second scan signal line 420 controls the second pixel circuits 23 to be turned on to control second light-emitting elements 24 to emit light. In the privacy-protection display mode, the scan signal in the first scan signal line 410 controls the first pixel circuits 21 to be turned on to control the first light-emitting elements 22 to emit light, while the scan signal in the second scan signal line 420 controls the second pixel circuits 23 to be turned off to control the second light-emitting elements 24 not to emit light.

Specifically, referring to FIG. 18, the display panel 10 further includes multiple pixel circuits and multiple signal lines that are located on one side of the substrate 100. A pixel circuit may include transistors and a capacitor, and the signal lines may include scan signal lines, data signal lines, power signal lines, and others. The pixel circuits are electrically connected to the scan signal lines, the data signal lines, the power signal lines, and others, and are configured to convert, under the action of scan signals provided by the scan signal lines, data signals provided by the data signal lines and power signals provided by the power signal lines into driving current signals for driving the light-emitting elements to emit light, thereby implementing the display of the light-emitting elements.

Specifically, referring to FIGS. 18 and 19, the first sub-pixel 200a includes the first pixel circuit 21 and the first light-emitting element 22 electrically connected to each other. The first pixel circuit 21 provides an electrical signal for the first light-emitting element 22 to drive the first light-emitting element 22 to emit light for display. The second sub-pixel 200b includes the second pixel circuit 23 and the second light-emitting element 24 electrically connected to each other. The second pixel circuit 23 provides an electrical signal for the second light-emitting element 24 to drive the second light-emitting element 24 to emit light for display. The first pixel circuits 21 and the second pixel circuits 23 in the same sub-pixel row 2000 are arranged along the third direction X3.

Referring to FIG. 18, the display panel 10 further includes the multiple scan signal lines 400 including the first scan signal line 410 and the second scan signal line 420. The first scan signal line 410 is electrically connected to the first pixel circuits 21 in the same sub-pixel row 2000. When the first scan signal line 410 provides the scan signal, the first pixel circuits 21 can drive the first light-emitting elements 22 to emit light for display. The second scan signal line 420 is electrically connected to the second pixel circuits 23 in the same sub-pixel row 2000. When the second scan signal line 420 provides the scan signal, the second pixel circuits 23 can drive the second light-emitting elements 24 to emit light for display.

Specifically, in the sharing display mode, the first light-emitting element 22 and the second light-emitting element 24 emit light, and in the privacy-protection display mode, the first light-emitting element 22 emits light while the second light-emitting element 24 does not emit light; that is, the light emission stages of different light-emitting elements or light-emitting portions are different. Therefore, the first pixel circuit 21 and the second pixel circuit 23 are independent of each other, and the light emission stage and light-emitting brightness of the first light-emitting element 22 and the light emission stage and light-emitting brightness of the second light-emitting element 24 are independently controlled by the first pixel circuit 21 and the second pixel circuit 23, respectively, thereby ensuring that the light emission control logic for the first light-emitting element 22 and the second light-emitting element 24 is simple and efficient.

Specifically, referring to FIG. 18, in the sharing display mode, the scan signal in the first scan signal line 410 controls the first pixel circuits 21 to be turned on to control the first light-emitting elements 22 to emit light, and the scan signal in the second scan signal line 420 controls the second pixel circuits 23 to be turned on to control the second light-emitting elements 24 to emit light, thereby enabling the first sub-pixel 200a and the second sub-pixel 200b to emit light for display. In the privacy-protection display mode, the scan signal in the first scan signal line 410 controls the first pixel circuits 21 to be turned on to control the first light-emitting elements 22 to emit light, while the scan signal in the second scan signal line 420 controls the second pixel circuits 23 to be turned off to control the second light-emitting elements 24 not to emit light, thereby enabling the first sub-pixel 200a to emit light for display and the second sub-pixel 200b not to emit light for display.

With continued reference to FIGS. 1 and 2, the display panel 10 further includes a light-emitting adjustment structure 300 located on one side of the sub-pixels 200 facing away from the substrate 100. The light-emitting adjustment structure 300 is provided with multiple first openings 300a and multiple second openings 300b, and the first openings 300a and the second openings 300b penetrate through the light-emitting adjustment structure 300. The projection of a first opening 300a on the plane on which the substrate 100 is located is a first opening projection, the projection of a second opening 300b on the plane on which the substrate 100 is located is a second opening projection, the projection of the pixel opening of the first sub-pixel 200a on the plane on which the substrate 100 is located is a first pixel opening projection, and the projection of the pixel opening of the second sub-pixel 200b on the plane on which the substrate 100 is located is a second pixel opening projection. The first opening projection at least partially overlaps the first pixel opening projection, and the second opening projection at least partially overlaps the second pixel opening projection. The minimum distance between the first opening projection and the first pixel opening projection is smaller than the minimum distance between the second opening projection and the second pixel opening projection.

Specifically, referring to FIG. 2, the display panel 10 includes the light-emitting adjustment structure 300 disposed on the side of the sub-pixels 200 facing away from the substrate 100. The light-emitting adjustment structure 300 can adjust the emitted light, thereby ensuring the light-emitting performance of the sub-pixels 200 in the display panel 10 and improving the overall display performance of the display panel 10.

Further, the light-emitting adjustment structure 300 includes the first openings 300a and the second openings 300b that penetrate through the light-emitting adjustment structure 300. The projection of the first opening 300a on the plane on which the substrate 100 is located at least partially overlaps the projection of the pixel opening of the first sub-pixel 200a (reference is made to the first pixel opening 102a in FIG. 2) on the plane on which the substrate 100 is located. The first opening 300a may be understood as a hollowed-out region of the light-emitting adjustment structure 300, and light is emitted from the first sub-pixel 200a through the corresponding hollowed-out region, thereby ensuring the light-emitting performance of the first sub-pixel 200a. Similarly, the projection of the second opening 300b on the plane on which the substrate 100 is located at least partially overlaps the projection of the pixel opening of the second sub-pixel 200b (reference is made to the second pixel opening 102b in FIG. 2) on the plane on which the substrate 100 is located. The second opening 300b may be understood as a hollowed-out region of the light-emitting adjustment structure 300, and light is emitted from the second sub-pixel 200b through the corresponding hollowed-out region, thereby ensuring the light-emitting performance of the second sub-pixel 200b.

Furthermore, to ensure that the maximum light-emitting viewing angle of the first sub-pixel 200a is smaller than that of the second sub-pixel 200b, the sizes of the first opening 300a and the second opening 300b in the light-emitting adjustment structure 300 may be adjusted. Specifically, the distance between the first opening projection and the first pixel opening projection is smaller to ensure the light-emitting performance of the first sub-pixel 200a at the front viewing angle, and the distance between the second opening projection and the second pixel opening projection is larger to ensure the light-emitting performance of the second sub-pixel 200b at the large viewing angle. Exemplarily, as shown in FIG. 2, along the second direction X2, the minimum distance between the first opening projection and the first pixel opening projection is m1, and the minimum distance between the second opening projection and the second pixel opening projection is m2. By adjusting m1 to be less than m2, the overall display performance of the display panel 10 can be ensured.

With continued reference to FIGS. 3 and 4, the display panel 10 further includes a light-emitting adjustment structure 300 located on one side of the sub-pixels 200 facing away from the substrate 100. The light-emitting adjustment structure 300 is provided with multiple first openings 300a and light-shielding portions 300c outside the first openings 300a, and the first openings 300a penetrate through the light-emitting adjustment structure 300. Along the first direction X1, a first opening 300a at least partially overlaps the first sub-pixel 200a, and a light-shielding portion 300c at least partially overlaps the second sub-pixel 200b.

Referring to FIGS. 3 and 4, the display panel 10 includes the light-emitting adjustment structure 300 located on the side of the sub-pixels 200 facing away from the substrate 100. The light-emitting adjustment structure 300 can adjust light emitted by the sub-pixels 200, thereby ensuring the display performance of the display panel 10. Specifically, referring to FIG. 4, the light-emitting adjustment structure 300 is provided with the multiple first openings 300a penetrating through the light-emitting adjustment structure 300. Moreover, the orthographic projection of the first opening 300a onto the substrate 100 overlaps the orthographic projection of the first sub-pixel 200a onto the substrate 100. Therefore, the light emitted by the first sub-pixel 200a can be emitted through the first opening 300a. It is to be noted that the first opening 300a adjusts the light emitted by the first sub-pixel 200a so that the light emission of the first sub-pixel 200a at the front viewing angle can be ensured. Further, referring to FIG. 4, the light-emitting adjustment structure 300 further includes the light-shielding portions 300c located outside the first openings 300a, and a light-shielding portion 300c at least partially overlaps the second sub-pixel 200b. Therefore, the light-shielding portion 300c shields the light emission of the second sub-pixel 200b at the front viewing angle, while the light emitted by the second sub-pixel 200b at the large viewing angle can be emitted through the first opening 300a, thereby enabling the second sub-pixel 200b to emit light at the large viewing angle.

With continued reference to FIGS. 2 and 4, the display panel 10 further includes a light-emitting adjustment structure 300 located on one side of the sub-pixel 200 facing away from the substrate 100. The light-emitting adjustment structure 300 includes a first light-shielding layer 311 and a second light-shielding layer 312, and the second light-shielding layer 312 is located on the side of the first light-shielding layer 311 facing away from the substrate 100. The first light-shielding layer 311 is provided with multiple first sub-openings 321 penetrating through the first light-shielding layer 311, and the second light-shielding layer 312 is provided with multiple second sub-openings 322 penetrating through the second light-shielding layer 312. Along the first direction X1, a first sub-opening 321 and a second sub-opening 322 overlap the first sub-pixel 200a.

Specifically, referring to FIGS. 2 and 4, the light-emitting adjustment structure 300 includes the first light-shielding layer 311 and the second light-shielding layer 312 that are disposed along the first direction X1, and the second light-shielding layer 312 is located on the side of the first light-shielding layer 311 facing away from the substrate 100. Through the cooperation of the first light-shielding layer 311 and the second light-shielding layer 312, the light-emitting viewing angle of the first sub-pixel 200a can be adjusted.

The first light-shielding layer 311 includes the multiple first sub-openings 321 penetrating through the first light-shielding layer 311, and the second light-shielding layer 312 includes the multiple second sub-openings 322 penetrating through the second light-shielding layer 312. Light is blocked when being transmitted to the first light-shielding layer 311 and the second light-shielding layer 312, and continues being emitted when being transmitted to the first sub-openings 321 and the second sub-openings 322. The first sub-opening 321 and the second sub-opening 322 overlap the first sub-pixel 200a along the first direction X1. Moreover, the first sub-opening 321 is closer to the first sub-pixel 200a than the second sub-opening 322. Therefore, the first sub-opening 321 can shield light emitted from an edge region of the first sub-pixel 200a at a relatively large viewing angle (reference is made to light n2 in FIG. 2), and the second sub-opening 322 can shield light emitted from an edge region of the first sub-pixel 200a at a relatively small viewing angle (reference is made to light n1 in FIG. 2). Accordingly, the first light-shielding layer 311 and the second light-shielding layer 312 that are disposed in different layers can block the light emitted by the first sub-pixel 200a at the large viewing angle, thereby ensuring the light-emitting performance of the first sub-pixel 200a at the front viewing angle. Further, by using the combination of the first light-shielding layer 311 and the second light-shielding layer 312 in different layers, the arrangement area of the light-shielding layer 310 parallel to the plane on which the substrate 100 is located can be effectively reduced, which can effectively improve the overall display performance of the display panel 10.

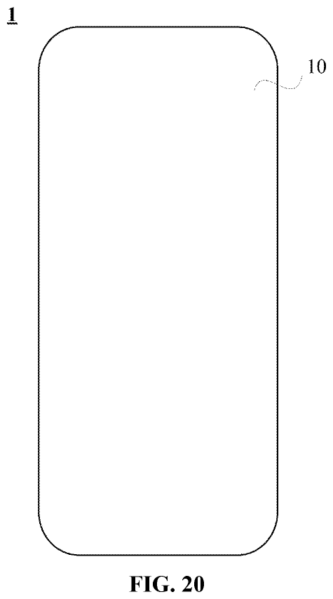

Based on the same inventive concept, an embodiment of the present application further provides a display device. FIG. 20 is a diagram illustrating the structure of a display device according to an embodiment of the present application. As shown in FIG. 20, the display device 1 includes the display panel 100 provided in any of the preceding embodiments, thereby having the same beneficial effects as the preceding embodiments. Details are not repeated herein. The display device 1 may be a mobile phone, a computer, a smart wearable device (such as a smartwatch), or an in-vehicle display device.

Apparently, the preceding embodiments of the present application are examples to illustrate the present application and are not intended to limit embodiments of the present application. Those of ordinary skill in the art can make various apparent modifications, adaptations, and substitutions without departing from the scope of the present application. All embodiments of the present application cannot be and do not need to be exhausted herein. Any modifications, equivalent substitutions, and improvements within the spirit and principle of the present application fall within the scope of the claims of the present application.

What is claimed is:

1. A display panel, comprising a substrate and a plurality of sub-pixels located on one side of the substrate, wherein
the plurality of sub-pixels comprise a first sub-pixel and a second sub-pixel that have a same emitted color, and a maximum light-emitting viewing angle of the first sub-pixel is smaller than a maximum light-emitting viewing angle of the second sub-pixel; and
display modes of the display panel comprise a sharing display mode and a privacy-protection display mode; wherein in the sharing display mode, both the first sub-pixel and the second sub-pixel are configured to emit light, and in the privacy-protection display mode, the first sub-pixel is configured to emit light and the second sub-pixel is configured not to emit light;
wherein the first sub-pixel comprises a first anode and a first cathode, and the first anode and the first cathode form a first microcavity structure; the second sub-pixel comprises a second anode and a second cathode, and the second anode and the second cathode form a second microcavity structure; along a first direction, a distance between the first anode and the first cathode is L1, and a distance between at least part of the second anode and at least part of the second cathode is L2, wherein the first direction is a thickness direction of the display panel; and
an emission wavelength of the first sub-pixel is λ1, an emission wavelength of the second sub-pixel is λ2, L1=n×(λ1/2), and L2≠m×(λ2/2), wherein n and m are each a positive integer.

2. The display panel according to claim 1, wherein the second sub-pixel comprises a first sub-pixel portion and a second sub-pixel portion, and the first sub-pixel portion surrounds at least part of the second sub-pixel portion;
the second anode comprises a first anode portion and a second anode portion that are connected, and the second cathode comprises a first cathode portion and a second cathode portion that are connected; the first sub-pixel portion comprises the first anode portion and the first cathode portion, and the second sub-pixel portion comprises the second anode portion and the second cathode portion; the second microcavity structure comprises a first microcavity structure portion formed by the first anode portion and the first cathode portion and a second microcavity structure portion formed by the second anode portion and the second cathode portion; and
along the first direction, at least a distance between the first anode portion and the first cathode portion is L2.

3. The display panel according to claim 2, wherein along the first direction, a distance between the second anode portion and the second cathode portion is L2, or
along the first direction, a distance between the second anode portion and the second cathode portion is L3, wherein L3=p×(λ2/2), and p is a positive integer.

4. The display panel according to claim 1, wherein the second sub-pixel surrounds at least part of the first sub-pixel.

5. The display panel according to claim 1, wherein the first sub-pixel further comprises a first light-emitting structure located between the first anode and the first cathode, and the first light-emitting structure comprises a plurality of first light-emitting material layers;
the second sub-pixel further comprises a second light-emitting structure located between the second anode and the second cathode, and the second light-emitting structure comprises a plurality of second light-emitting material layers; and at least one of the following is satisfied:
the plurality of first light-emitting material layers in the first light-emitting structure have a different number from the plurality of second light-emitting material layers in at least part of the second light-emitting structure, or a thickness of at least one of the plurality of first light-emitting material layers is different from a thickness of at least one of the plurality of second light-emitting material layers in at least part of the second light-emitting structure.

6. The display panel according to claim 1, wherein the first sub-pixel further comprises a first light-emitting structure located between the first anode and the first cathode, and the first light-emitting structure comprises a first light-emitting unit layer, a first charge generation layer, and a second light-emitting unit layer that are stacked along the first direction; and
the first light-emitting unit layer, the first charge generation layer, and the second light-emitting unit layer each comprise a plurality of first light-emitting material layers.

7. The display panel according to claim 6, wherein the second sub-pixel further comprises a second light-emitting structure located between the second anode and the second cathode, and the second light-emitting structure comprises at least one light-emitting unit layer; and
each of the at least one light-emitting unit layer comprises a plurality of second light-emitting material layers.

8. The display panel according to claim 7, wherein the second light-emitting structure comprises a third light-emitting unit layer, a second charge generation layer, and a fourth light-emitting unit layer that are stacked along the first direction; and
the third light-emitting unit layer, the second charge generation layer, and the fourth light-emitting unit layer each comprise a plurality of second light-emitting material layers.

9. The display panel according to claim 7, wherein the second light-emitting structure comprises a fifth light-emitting unit layer; and
the fifth light-emitting unit layer comprises a plurality of second light-emitting material layers.

10. The display panel according to claim 7, wherein the second sub-pixel comprises a first sub-pixel portion and a second sub-pixel portion, and the first sub-pixel portion surrounds at least part of the second sub-pixel portion;
the second anode comprises a first anode portion and a second anode portion that are connected, and the second cathode comprises a first cathode portion and a second cathode portion that are connected; the first sub-pixel portion comprises the first anode portion and the first cathode portion, and the second sub-pixel portion comprises the second anode portion and the second cathode portion;
the first sub-pixel portion further comprises a first light-emitting structure portion located between the first anode portion and the first cathode portion, and the second sub-pixel portion further comprises a second light-emitting structure portion located between the second anode portion and the second cathode portion;
the first light-emitting structure portion comprises a sixth light-emitting unit layer;
the second light-emitting structure portion comprises a seventh light-emitting unit layer, a third charge generation layer, and an eighth light-emitting unit layer that are stacked along the first direction; and
the sixth light-emitting unit layer, the seventh light-emitting unit layer, the third charge generation layer, and the eighth light-emitting unit layer each comprise a plurality of second light-emitting material layers.

11. The display panel according to claim 10, wherein the sixth light-emitting unit layer comprises a first hole injection layer, a first hole transport layer, a first emitting layer, a first electron transport layer, and a first electron injection layer that are stacked along the first direction; and
the seventh light-emitting unit layer comprises a second hole injection layer, a second hole transport layer, a second emitting layer, and a second electron transport layer that are stacked along the first direction; the third charge generation layer comprises an n-type charge generation layer and a p-type charge generation layer that are stacked along the first direction; the eighth light-emitting unit layer comprises a third emitting layer, a third electron transport layer, and a second electron injection layer that are stacked along the first direction; wherein
the first hole injection layer is disposed in a same layer as the second hole injection layer, the first hole transport layer is disposed in a same layer as the second hole transport layer, the first emitting layer is disposed in a same layer as the second emitting layer, the first electron transport layer is disposed in a same layer as the second electron transport layer or the third electron transport layer, and the first electron injection layer is disposed in a same layer as the second electron injection layer.

12. The display panel according to claim 10, wherein an opening area of the second sub-pixel is greater than or equal to an opening area of the first sub-pixel; and
an opening area of the second sub-pixel portion is smaller than the opening area of the first sub-pixel.

13. The display panel according to claim 10, wherein the second sub-pixel comprises a first-color second sub-pixel, a second-color second sub-pixel, and a third-color second sub-pixel,
wherein a luminescence efficiency of the first-color second sub-pixel is higher than a luminescence efficiency of the second-color second sub-pixel, and the luminescence efficiency of the second-color second sub-pixel is higher than a luminescence efficiency of the third-color second sub-pixel;
wherein in the first-color second sub-pixel, a length of the first sub-pixel portion located on one side of the second sub-pixel portion in a second direction is d11, and a length of the second sub-pixel portion in the second direction is d12; in the second-color second sub-pixel, a length of the first sub-pixel portion located on one side of the second sub-pixel portion in the second direction is d21, and a length of the second sub-pixel portion in the second direction is d22; and in the third-color second sub-pixel, a length of the first sub-pixel portion located on one side of the second sub-pixel portion in the second direction is d31, and a length of the second sub-pixel portion in the second direction is d32; wherein the second direction is parallel to a plane on which the substrate is located;
wherein d11/d12>d21/d22>d31/d32.

14. The display panel according to claim 4, wherein the second sub-pixel further comprises a second light-emitting structure located between the second anode and the second cathode, and the second light-emitting structure comprises one light-emitting unit layer; and
the plurality of sub-pixels comprise a first-color sub-pixel, a second-color sub-pixel, and a third-color sub-pixel, the first-color sub-pixel, the second-color sub-pixel, and the third-color sub-pixel each comprise the first sub-pixel and the second sub-pixel, a luminescence efficiency of the first-color sub-pixel is higher than a luminescence efficiency of the second-color sub-pixel, and the luminescence efficiency of the second-color sub-pixel is higher than a luminescence efficiency of the third-color sub-pixel; wherein
in the first-color sub-pixel, a length of the second sub-pixel located on one side of the first sub-pixel in a second direction is d41, and a length of the first sub-pixel in the second direction is d42; in the second-color sub-pixel, a length of the second sub-pixel located on one side of the first sub-pixel in the second direction is d51, and a length of the first sub-pixel in the second direction is d52; in the third-color sub-pixel, a length of the second sub-pixel located on one side of the first sub-pixel in the second direction is d61, and a length of the first sub-pixel in the second direction is d62; wherein the second direction is parallel to a plane on which the substrate is located; and
d41/d42>d51/d52>d61/d62.

15. The display panel according to claim 4, wherein the first sub-pixel comprises a first pixel circuit and a first light-emitting element electrically connected to each other, the second sub-pixel comprises a second pixel circuit and a second light-emitting element electrically connected to each other, and the first pixel circuit also serves as the second pixel circuit; and
the display panel further comprises a switch unit and a control module, wherein
the switch unit is connected in series between the second pixel circuit and the second light-emitting element, and the control module is electrically connected to the switch unit; and
in the sharing display mode, the control module is configured to control the switch unit to be turned on to turn on the second pixel circuit and the second light-emitting element; and in the privacy-protection display mode, the control module is further configured to control the switch unit to be turned off to turn off the second pixel circuit and the second light-emitting element.

16. The display panel according to claim 4, further comprising a plurality of sub-pixel rows, wherein a sub-pixel row among the plurality of sub-pixel rows comprises a plurality of first sub-pixels arranged along a third direction and a plurality of second sub-pixels arranged along the third direction, and the plurality of sub-pixel rows are arranged along a fourth direction; wherein the third direction and the fourth direction intersect and are both parallel to a plane on which the substrate is located;
the first sub-pixel comprises a first pixel circuit and a first light-emitting element electrically connected to each other, and the second sub-pixel comprises a second pixel circuit and a second light-emitting element electrically connected to each other; the first pixel circuit and the second pixel circuit are independent of each other, and first pixel circuits and second pixel circuits in a same sub-pixel row among the plurality of sub-pixel rows are arranged along the third direction;
the display panel further comprises a plurality of scan signal lines, the plurality of scan signal lines comprise a first scan signal line and a second scan signal line, and both the first scan signal line and the second scan signal line extend along the third direction and are arranged along the fourth direction;
among the first pixel circuits and the second pixel circuits in the same sub-pixel row, the first pixel circuits are electrically connected to the first scan signal line, and the second pixel circuits are electrically connected to the second scan signal line;
in a sharing display mode, a scan signal in the first scan signal line is configured to control the first pixel circuits to be turned on to control first light-emitting elements to emit light, and a scan signal in the second scan signal line is configured to control the second pixel circuits to be turned on to control second light-emitting elements to emit light; and
in a privacy-protection display mode, the scan signal in the first scan signal line is configured to control the first pixel circuits to be turned on to control the first light-emitting elements to emit light, and the scan signal in the second scan signal line is configured to control the second pixel circuits to be turned off to control the second light-emitting elements not to emit light.

17. The display panel according to claim 2, further comprising a light-emitting adjustment structure located on a side of the plurality of sub-pixels facing away from the substrate, wherein the light-emitting adjustment structure is provided with a plurality of first openings and a plurality of second openings, and each opening among the plurality of first openings and the plurality of second openings penetrates through the light-emitting adjustment structure;
a projection of a first opening among the plurality of first openings on a plane on which the substrate is located is a first opening projection, a projection of a second opening among the plurality of second openings on the plane on which the substrate is located is a second opening projection, a projection of a pixel opening of the first sub-pixel on the plane on which the substrate is located is a first pixel opening projection, and a projection of a pixel opening of the second sub-pixel on the plane on which the substrate is located is a second pixel opening projection;
the first opening projection at least partially overlaps the first pixel opening projection, and the second opening projection at least partially overlaps the second pixel opening projection; and
a minimum distance between the first opening projection and the first pixel opening projection is smaller than a minimum distance between the second opening projection and the second pixel opening projection.

18. The display panel according to claim 4, further comprising a light-emitting adjustment structure located on a side of the plurality of sub-pixels facing away from the substrate, wherein the light-emitting adjustment structure is provided with a plurality of first openings and light-shielding portions outside the plurality of first openings, and each of the plurality of first openings penetrates through the light-emitting adjustment structure; and
along the first direction, a first opening among the plurality of first openings at least partially overlaps the first sub-pixel, and a light-shielding portion among the light-shielding portions at least partially overlaps the second sub-pixel.

19. The display panel according to claim 1, further comprising a light-emitting adjustment structure located on a side of the plurality of sub-pixels facing away from the substrate, wherein the light-emitting adjustment structure comprises a first light-shielding layer and a second light-shielding layer, and the second light-shielding layer is located on a side of the first light-shielding layer facing away from the substrate; wherein
the first light-shielding layer is provided with a plurality of first sub-openings penetrating through the first light-shielding layer, and the second light-shielding layer is provided with a plurality of second sub-openings penetrating through the second light-shielding layer; and
along the first direction, a first sub-opening among the plurality of first sub-openings and a second sub-opening among the plurality of second sub-openings overlap the first sub-pixel.

20. A display device, comprising a display panel, wherein the display panel comprises a substrate and a plurality of sub-pixels located on one side of the substrate, wherein
the plurality of sub-pixels comprise a first sub-pixel and a second sub-pixel that have a same emitted color, and a maximum light-emitting viewing angle of the first sub-pixel is smaller than a maximum light-emitting viewing angle of the second sub-pixel; and
display modes of the display panel comprise a sharing display mode and a privacy-protection display mode; wherein in the sharing display mode, both the first sub-pixel and the second sub-pixel are configured to emit light, and in the privacy-protection display mode, the first sub-pixel is configured to emit light and the second sub-pixel is configured not to emit light;
wherein the first sub-pixel comprises a first anode and a first cathode, and the first anode and the first cathode form a first microcavity structure; the second sub-pixel comprises a second anode and a second cathode, and the second anode and the second cathode form a second microcavity structure; along a first direction, a distance between the first anode and the first cathode is L1, and a distance between at least part of the second anode and at least part of the second cathode is L2, wherein the first direction is a thickness direction of the display panel; and
an emission wavelength of the first sub-pixel is λ1, an emission wavelength of the second sub-pixel is λ2, L1=n×(λ1/2), and L2≠m ×(λ2/2), wherein n and m are each a positive integer.
